(19) United States
(12) Patent Application Publication
(10) Pub. No.: US 2026/0362795 A1
(43) Pub. Date: Nov. 12, 2026

(54) SEMICONDUCTOR STRUCTURE AND METHOD OF MANUFACTURING SAME

(71) Applicant: Taiwan Semiconductor Manufacturing Company, Ltd., Hsin-Chu (TW)

(72) Inventors: Ting-Yeh Chen, Hsinchu City (TW); Wei-Yang Lee, Taipei City (TW)

(21) Appl. No.: 19/333,717

(22) Filed: Sep. 19, 2025

Related U.S. Application Data
(60) Provisional application No. 63/803,201, filed on May 9, 2025.

(51) Int. Cl. H10D 84/83; H10D 30/00; H10D 30/01; H10D 30/43; H10D 62/10; H10D 62/13; H10D 64/01; H10D 84/01

(52) U.S. Cl. CPC H10D 84/832; H10D 30/014; H10D 30/0191; H10D 30/43; H10D 30/506; H10D 62/102; H10D 62/116; H10D 62/121; H10D 62/151; H10D 64/017; H10D 84/013; H10D 84/0142; H10D 84/8311; H10D 84/8312; H10D 84/83138

(57) ABSTRACT

A method includes providing a stack of alternating channel layers and sacrificial layers, forming a dummy gate over a channel region of the stack, depositing a first spacer layer along sidewalls of the dummy gate, depositing a second spacer layer along sidewalls of the first spacer layer, trimming the second spacer layer, performing a first etching process in a source/drain region of the stack, thereby forming a shallow recess, performing a second etching process to form a source/drain recess, forming a source/drain feature in the source/drain recess, forming a contact etch stop layer (CESL) and an interlayer dielectric layer over the source/drain feature, and replacing the dummy gate and the sacrificial layers with a metal gate. The source/drain feature includes a first layer adjacent the channel layers and a second layer away from the channel layers.

### PRIORITY DATA

The present application claims the benefit of U.S. Provisional Application No. 63/803,201, filed May 9, 2025, the entirety of which is herein incorporated by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, pitch loading effect in forming source/drain recesses may result in channels with increased widths, and may increase parasitic capacitance and reduce speed of devices. Therefore, although existing structures and methods have been generally adequate for their intended purposes, they are not entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flow chart of a method for fabricating a semiconductor structure according to various aspects of the present disclosure.

FIGS. 2, 3, 4, 5, 6, 7, 8, 9, 10A, 10B, 11, 12, 13A, 13B, 14, and 15 illustrate fragmentary cross-sectional views of an exemplary structure at various fabrication stages associated with the method of FIG. 1 according to various aspects of the present disclosure.

FIG. 16 illustrates a flow chart of an alternative method for fabricating a semiconductor structure according to various aspects of the present disclosure.

FIG. 17 illustrates a fragmentary cross-sectional view of an exemplary structure at various fabrication stages associated with the method of FIG. 16 according to various aspects of the present disclosure.

FIGS. 18 and 19 illustrate fragmentary cross-sectional views of an exemplary structure at various fabrication stages associated with the method of FIG. 1 or FIG. 16 according to various aspects of the present disclosure.

FIGS. 20 and 21 illustrate fragmentary cross-sectional views of an exemplary structure at various fabrication stages associated with the method of FIG. 1 or FIG. 16 according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Other ranges are possible as known by those skilled in the art and may be process dependent.

As integrated circuit (IC) technologies progress towards smaller technology nodes, multi-gate devices are introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A gate-all-around (GAA) transistor has a gate structure that can extend, partially or fully, around a channel region to provide access to the channel region on two or more sides. The channel region of a GAA transistor may be formed from nanowires, nanosheets, other nanostructures, and/or other suitable structures. The shapes of the channel region have also given a GAA transistor alternative names such as a nanosheet transistor or a nanowire transistor.

Source/drain recess etching may have pitch loading effect, which may result in increased channel widths, especially in regions having a larger gate pitch. Longer channel widths may cause relatively far junction overlap, increase parasitic capacitance, and reduce device speed, which may impact the overall performance of a device. Thus, although existing structures and methods have been generally adequate for their intended purposes, they are not entirely satisfactory in every aspect.

The present disclosure is generally related to semiconductor structures and manufacturing methods of forming same. More specifically, the present disclosure is related to forming a semiconductor structure with reduced channel widths in a region of the semiconductor structure. In some embodiments, a method disclosed herein includes providing a structure including a stack of alternating channel layers and sacrificial layers. The method further includes forming fin-shaped structures from the stack, forming dummy gate stacks over the fin-shaped structures, depositing a first gate spacer layer over the dummy gate stacks, and depositing a second gate spacer layer over the first gate spacer layer. The structure includes a first region and a second region. The first region may have a smaller gate pitch than the second region. In some embodiments, the method further includes trimming the second gate spacer layer in the second region but not the first region, performing a first etching process to source/drain regions of the fin-shaped structures to form initial recesses, performing a nitridation process to the initial recesses, performing a second etching process to extend the initial recesses to form source/drain recesses, and forming source/drain features in the source/drain recesses. The structure may then undergo further processes to form a final structure. Because of the trimming of the second gate spacer layer, a total thickness of the first gate spacer layer and the second gate spacer layer in the second region is reduced. Thus, the source/drain recesses and the source/drain features in the second region are widened, and the channel layers in the second region may have reduced widths. Benefits may include that parasitic capacitance may be reduced, and device speed may be increased, thus the overall performance of the structure may be improved.

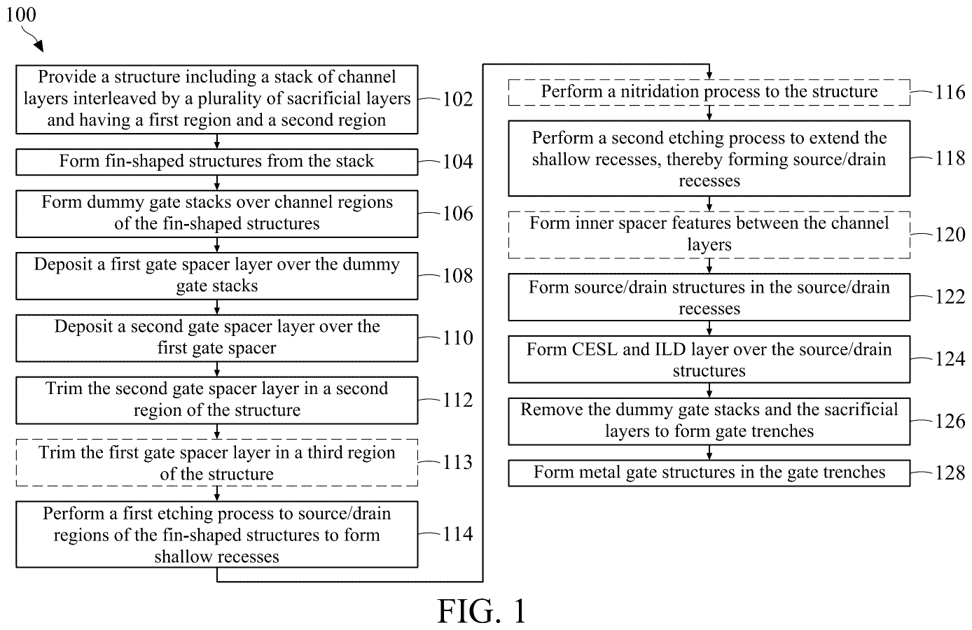

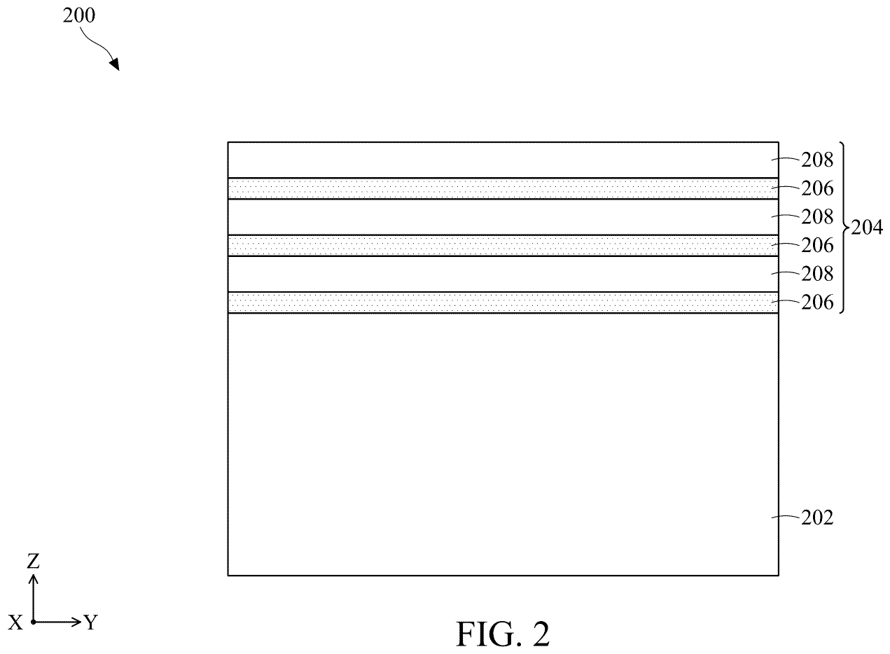

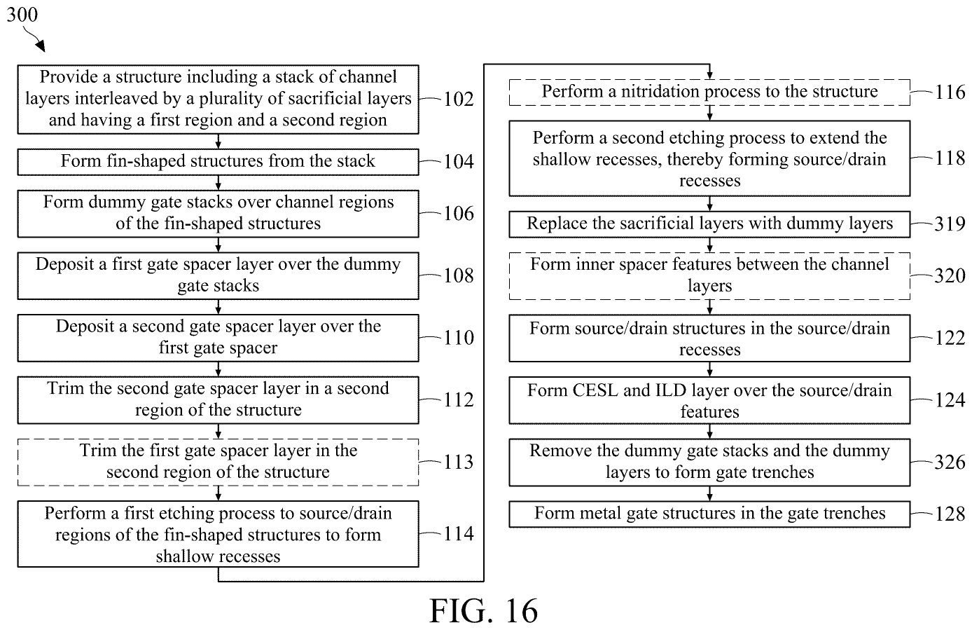

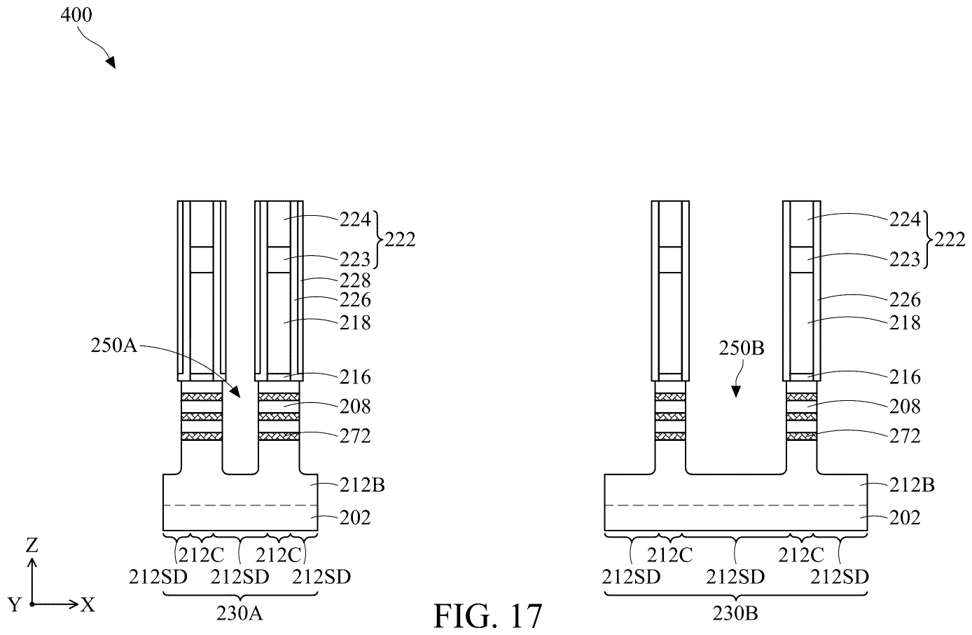

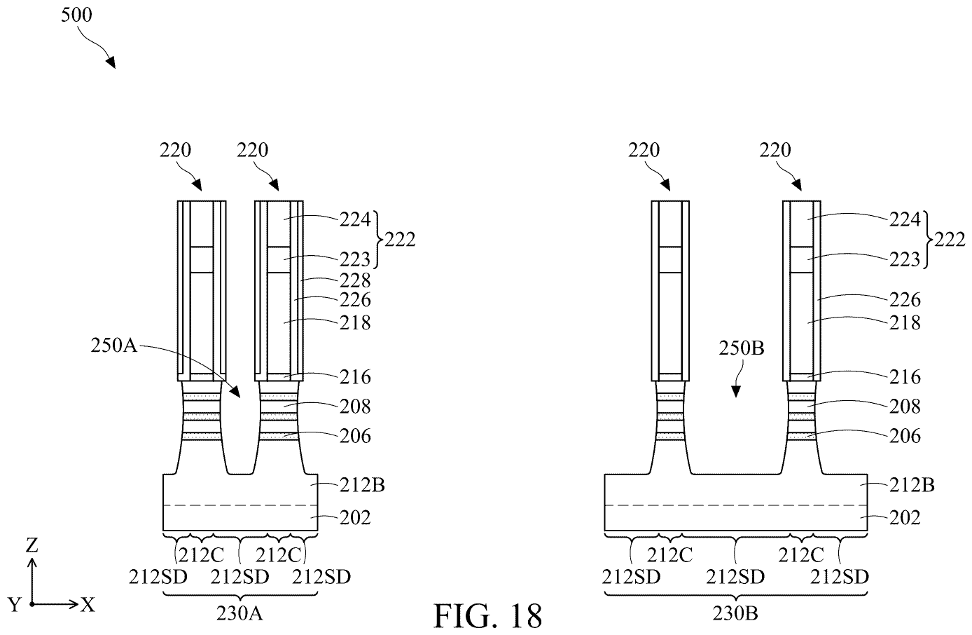

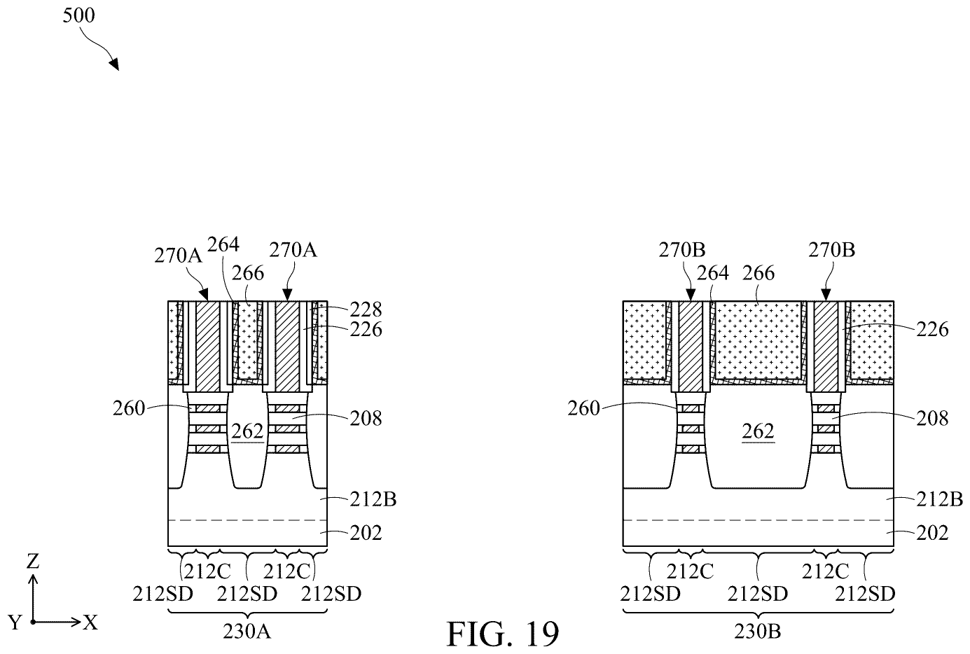

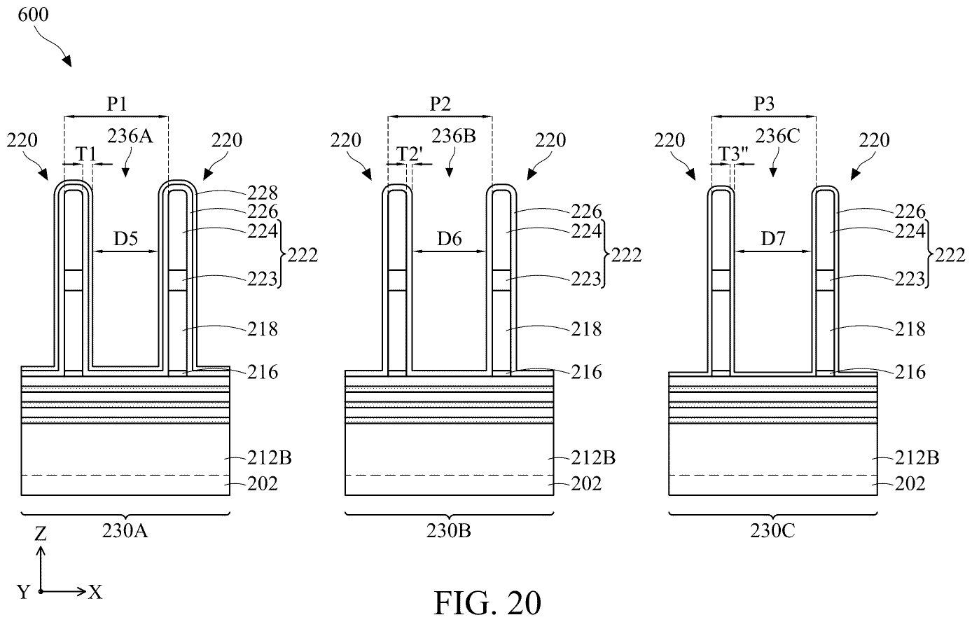

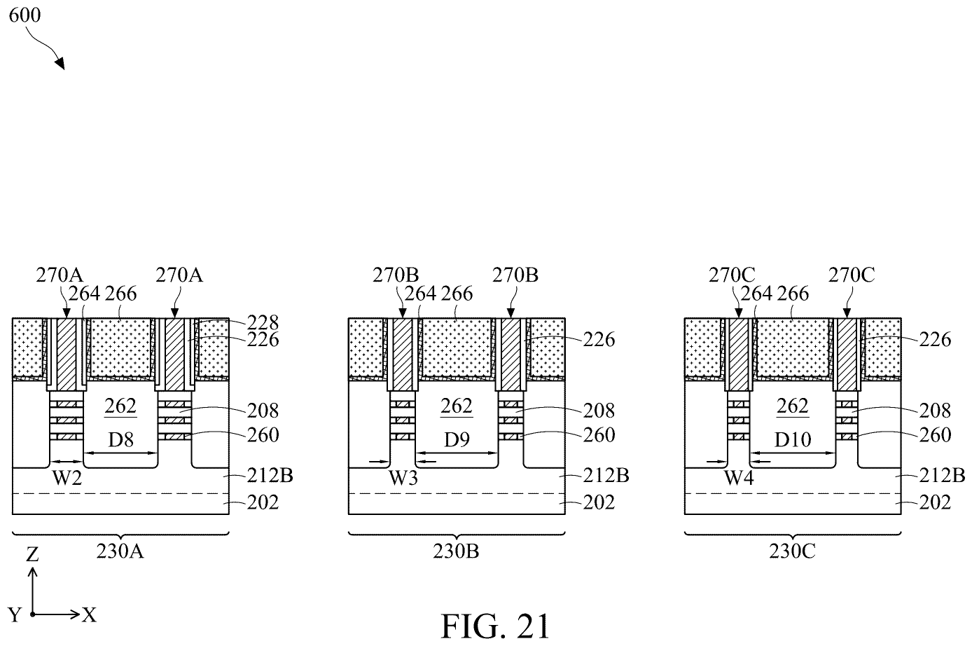

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2-15, which are fragmentary cross-sectional views of a structure 200 at different stages of fabrication according to embodiments of method 100 in FIG. 1. FIG. 16 is a flowchart illustrating method 300 of forming a semiconductor structure according to embodiments of the present disclosure. FIG. 17 is a fragmentary cross-sectional view of a structure 400 at different stages of fabrication according to embodiments of method 300 in FIG. 16. FIGS. 18-19 are fragmentary cross-sectional views of a structure 500 at different stages of fabrication according to embodiments of method 100 in FIG. 1 or method 300 in FIG. 16. FIGS. 20-21 are fragmentary cross-sectional views of a structure 600 at different stages of fabrication according to embodiments of method 100 in FIG. 1 or method 300 in FIG. 16. Method 100 (or 300) is merely an example and is not intended to limit the present disclosure to what is explicitly illustrated in method 100 (or 300). Additional steps can be provided before, during, and after method 100 (or 300), and some steps described can be replaced, eliminated, or moved around for additional embodiments of method 100 (or 300). Not all steps are described herein in detail for reasons of simplicity. Because the structure 200 (or 400, 500, 600) will be fabricated into a semiconductor structure, the structure 200 (or 400, 500, 600) may be referred to herein as a semiconductor structure 200 (or 400, 500, 600) or a semiconductor device 200 (or 400, 500, 600) as the context requires. For avoidance of doubts, the X, Y and Z directions in FIGS. 2-15 and 17-21 are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

Referring to FIGS. 1-2, method 100 includes a block 102 where a structure 200 is formed or provided. As shown in FIG. 2, the structure 200 includes a substrate 202 and a stack 204 of alternating semiconductor layers formed over the substrate 202. In some embodiments, the substrate 202 may be a semiconductor substrate such as a silicon (Si) substrate. The substrate 202 may include various doping configurations depending on design requirements as is known in the art. In embodiments where the semiconductor device is p-type, an n-type doping profile (i.e., an n-type well or n-well) may be formed on the substrate 202. In some implementations, the n-type dopant for forming the n-type well may include phosphorus (P), arsenic (As), or antimony (Sb). In embodiments where the semiconductor device is n-type, a p-type doping profile (i.e., a p-type well or p-well) may be formed on the substrate 202. In some implementations, the p-type dopant for forming the p-type well may include boron (B) or gallium (Ga). The suitable doping may include ion implantation of dopants and/or diffusion processes. The substrate 202 may also include other semiconductors such as germanium (Ge), silicon carbide (SiC), silicon germanium (SiGe), germanium tin (GeSn), or diamond. Alternatively, the substrate 202 may include a compound semiconductor and/or an alloy semiconductor. Further, the substrate 202 may optionally include an epitaxial layer (epi-layer), may be strained for performance enhancement, may include a silicon-on-insulator (SOI) or a germanium-on-insulator (GeOI) structure, and/or may have other suitable enhancement features.

In some embodiments, the stack 204 over the substrate 202 includes channel layers 208 of a first semiconductor composition interleaved by sacrificial layers 206 of a second semiconductor composition. It can also be said that the sacrificial layers 206 are interleaved by the channel layers 208. The first and second semiconductor composition may be different. In some embodiments, the sacrificial layers 206 include silicon germanium (SiGe) or germanium tin (GeSn) and the channel layers 208 include silicon (Si). It is noted that three (3) layers of the sacrificial layers 206 and three (3) layers of the channel layers 208 are alternately arranged as illustrated in FIG. 2, which is for illustrative purposes only and not intended to be limiting beyond what is specifically recited in the claims. It can be appreciated that any number of epitaxial layers may be formed in the stack 204. The number of layers depends on the desired number of channel members for the semiconductor device 200. In some embodiments, the number of channel layers 208 is between 2 and 10.

The sacrificial layers 206 and channel layers 208 in the stack 204 may be deposited using a molecular beam epitaxy (MBE) process, a vapor phase epitaxy (VPE) process, and/or other suitable epitaxial growth processes. As stated above, in at least some examples, the sacrificial layers 206 include an epitaxially grown silicon germanium (SiGe) layer and the channel layers 208 include an epitaxially grown silicon (Si) layer. In some embodiments, the sacrificial layers 206 and the channel layers 208 are substantially dopant-free (i.e., having an extrinsic dopant concentration from about 0 atoms/cm³ to about 1×10¹⁷ atoms/cm³), where for example, no intentional doping is performed during the epitaxial growth processes for the stack 204.

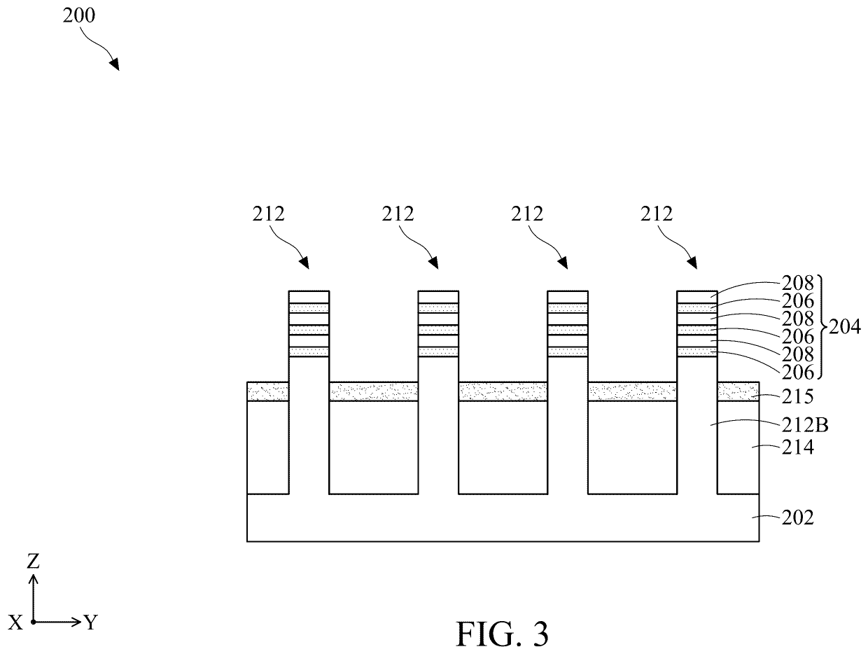

Referring to FIGS. 1 and 3, method 100 includes a block 104 where fin-shaped structures 212 (also referred to as active regions 212) are formed from the stack 204 and the substrate 202. To pattern the stack 204, a hard mask layer may be deposited over the stack 204 to form an etch mask. The hard mask layer may be a single layer or a multi-layer. For example, the hard mask layer may include a pad oxide layer and a pad nitride layer disposed over the pad oxide layer. The fin-shaped structure 212 may be patterned from the stack 204 and the substrate 202 using a lithography process and an etch process. The lithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etching (e.g., RIE etching), wet etching, and/or other etching methods. As shown in FIG. 3, the etch process at block 104 forms trenches extending vertically through the stack 204 and a portion of the substrate 202. The trenches define the fin-shaped structures 212. In some implementations, double-patterning or multi-patterning processes may be used to define fin-shaped structures that have, for example, pitches smaller than what is otherwise obtainable using a single, direct photolithography process. For example, in one embodiment, a material layer is formed over a substrate and patterned using a photolithography process. Spacers are formed alongside the patterned material layer using a self-aligned process. The material layer is then removed, and the remaining spacers, or mandrels, may then be used to pattern the fin-shaped structure 212 by etching the stack 204 and a portion of the substrate 202. As shown in FIG. 3, the fin-shaped structure 212 that includes the sacrificial layers 206 and the channel layers 208 extends vertically along the Z direction and lengthwise along the X direction. As shown in FIG. 3, the fin-shaped structure 212 includes a base fin structure 212B patterned from the substrate 202. The patterned stack 204, including the sacrificial layers 206 and the channel layers 208, is disposed directly over the base fin structure 212B.

An isolation feature 214 is formed adjacent to the fin-shaped structure 212. In some embodiments represented in FIG. 3, the isolation feature 214 is disposed on sidewalls of the base fin structure 212B. In some embodiments, the isolation feature 214 may be formed in the trenches to isolate the fin-shaped structures 212 from a neighboring fin-shaped structure 212. The isolation feature 214 may also be referred to as a shallow trench isolation (STI) feature 214. By way of example, in some embodiments, a dielectric layer is first deposited over the substrate 202, filling the trenches with the dielectric layer. In some embodiments, the dielectric layer may include silicon oxide, silicon oxynitride, fluorine-doped silicate glass (FSG), a low-k dielectric, combinations thereof, and/or other suitable materials. In various examples, the dielectric layer may be deposited by a chemical vapor deposition (CVD) process, a subatmospheric CVD (SACVD) process, a flowable CVD process, a spin-on coating process, and/or other suitable process. The deposited dielectric material is then thinned and planarized, for example by a chemical mechanical polishing (CMP) process. The planarized dielectric layer is further recessed or pulled-back by a dry etching process, a wet etching process, and/or a combination thereof to form the STI feature 214 shown in FIG. 3. The fin-shaped structure 212 rises above the STI feature 214 after the recessing, while the base fin structure 212B is at least partially embedded or buried in the isolation feature 214.

Still referring to FIGS. 1 and 3, a protecting layer 215 is formed over the isolation structure 214 and around a top portion of the fin-shaped base 212B. A composition of the protecting layer 215 is different from a composition of the isolation structure 214. In some embodiments, the isolation structure 214 includes silicon oxide (SiOx, e.g., SiO₂), and the protecting layer 215 includes silicon nitride (SiₓN_{y}, e.g., SiN, Si₃N₄), silicon carbonitride (SiCN), or silicon oxynitride (SiON). By way of example, in some embodiments, a nitride-containing material is first deposited over the isolation structure 214, filling the trenches. In various examples, the nitride-containing material may be deposited by a CVD process, a subatmospheric CVD (SACVD) process, a flowable CVD process, a spin-on coating process, and/or other suitable process. The deposited nitride-containing material is then thinned and planarized, for example by a chemical mechanical polishing (CMP) process. The planarized nitride-containing material is further recessed or pulled-back by a dry etching process, a wet etching process, and/or a combination thereof to form the protecting layer 215. The fin-shaped structures 212 rise above the protecting layer 215 after the recessing. The fin-shaped base 212B is embedded or buried in the combination of the isolation structure 214 and the protecting layer 215.

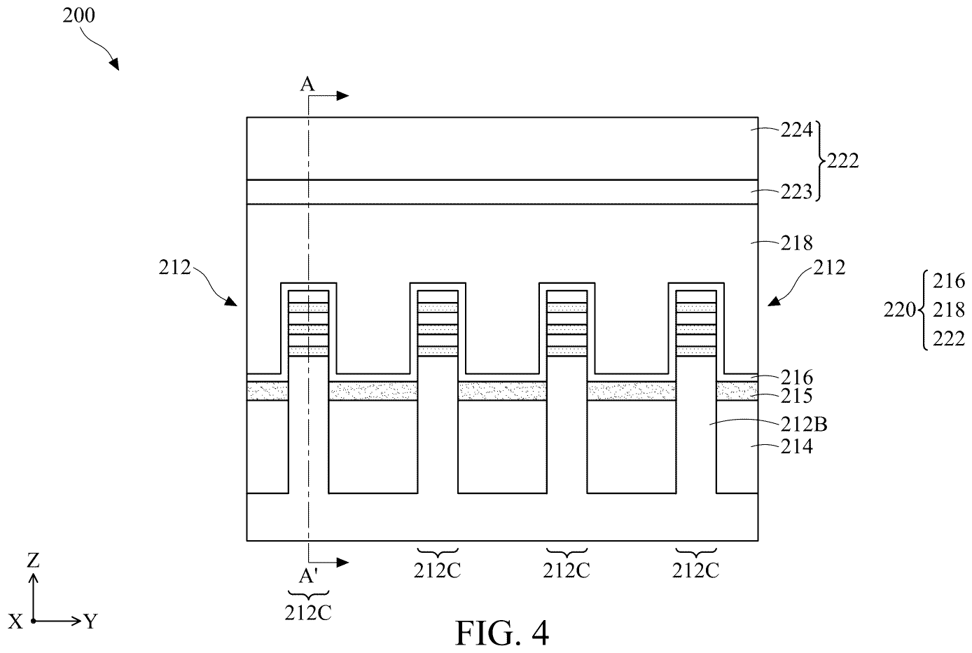

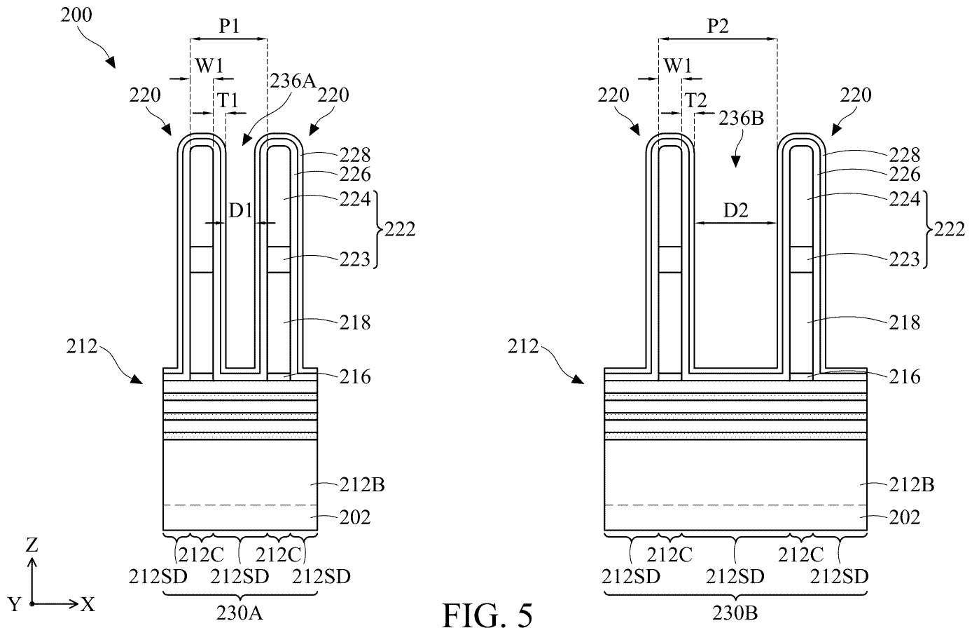

Referring to FIGS. 1, 4, and 5, method 100 includes a block 106 where dummy gate stacks 220 are formed over channel regions 212C of the fin-shaped structures 212. FIG. 5 illustrates a fragmentary cross-section view of the structure 200 taken along line A-A′ as in FIG. 4. In some embodiments, a gate replacement process (or gate-last process) is adopted where the dummy gate stacks 220 (shown in FIGS. 4 and 5) serve as a placeholder to undergo various processes and are to be removed and replaced by functional gate structures. Other processes and configuration are possible. In some embodiments illustrated in FIG. 5, the dummy gate stacks 220 are formed over the fin-shaped structure 212 and the fin-shaped structure 212 may be divided into channel regions 212C underlying the dummy gate stacks 220 and source/drain regions 212SD that do not underlie the dummy gate stacks 220. The channel regions 212C are adjacent to the source/drain regions 212SD. As shown in FIG. 5, the channel region 212C is disposed between two source/drain regions 212SD along the X direction. The dummy gate stacks 220 may extend lengthwise along the Y direction.

The formation of the dummy gate stack 220 may include deposition of layers in the dummy gate stack 220 and patterning of these layers. Referring to FIG. 4, a dummy dielectric layer 216, a dummy electrode layer 218, and a gate-top hard mask layer 222 may be blanketly deposited over the structure 200. In some embodiments, the dummy dielectric layer 216 may be formed on the fin-shaped structure 212 using a chemical vapor deposition (CVD) process, an atomic layer deposition (ALD) process, an oxygen plasma oxidation process, or other suitable processes. In some instances, the dummy dielectric layer 216 may include silicon oxide. Thereafter, the dummy electrode layer 218 may be deposited over the dummy dielectric layer 216 using a CVD process, an ALD process, or other suitable processes. In some instances, the dummy electrode layer 218 may include polysilicon. For patterning purposes, the gate-top hard mask layer 222 may be deposited on the dummy electrode layer 218 using a CVD process, an ALD process, or other suitable processes. The gate-top hard mask layer 222, the dummy electrode layer 218 and the dummy dielectric layer 216 may then be patterned to form the dummy gate stack 220, as shown in FIG. 5. For example, the patterning process may include a lithography process (e.g., photolithography or e-beam lithography) and an etching process. The lithography process may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The photolithography process forms a patterned photoresist layer. The patterned photoresist layer is then applied as an etch mask in the etching process to pattern the gate-top hard mask layer 222, the dummy electrode layer 218 and the dummy dielectric layer 216. In some embodiments, the etching process may include dry etching (e.g., RIE etching), wet etching, and/or other etching methods. In some embodiments, the gate-top hard mask layer 222 may include a silicon oxide layer 223 and a silicon nitride layer 224 over the silicon oxide layer 223. As shown in FIG. 5, the dummy gate stack 220 is patterned such that it is only disposed over the channel region 212C, not disposed over the source/drain region 212SD.

Referring to FIGS. 1 and 5, method 100 includes a block 108 where a first gate spacer layer 226 is deposited over the structure 200, including over the dummy gate stacks 220. In some embodiments, the first gate spacer layer 226 is deposited conformally over the structure 200, including over top surfaces and sidewalls of the dummy gate stacks 220. The term “conformally” may be used herein for ease of description of a layer having substantially uniform thickness over various regions. The first gate spacer layer 226 may be a single layer or a multi-layer. The at least one layer in the first gate spacer layer 226 may include silicon carbonitride, silicon oxycarbide, silicon oxycarbonitride, or silicon nitride. The first gate spacer layer 226 may be deposited over the dummy gate stacks 220 using processes such as, a CVD process, a subatmospheric CVD (SACVD) process, an ALD process, or other suitable process.

Still referring to FIGS. 1 and 5, method 100 includes a block 110 where a second gate spacer layer 228 is deposited over the first gate spacer layer 226. The first gate spacer layer 226 and the second gate spacer layer 228 can be individually or collectively referred to as gate spacer layer(s), depending on the context. The second gate spacer layer 228 may be deposited conformally. The second gate spacer layer 228 may be a single layer or a multi-layer. The second gate spacer layer 228 may include a same or different composition from the first gate spacer layer 226 and may be formed using processes similar as forming the first gate spacer layer 226.

Referring to FIG. 5, the structure 200 may include a first region 230A and a second region 230B. The first region 230A and the second region 230B may be adjacent to or separated from each other. The fin-shaped structure(s) 212 as depicted in the first region 230A and the second region 230B may be a same fin-shaped structure 212 or different fin-shaped structures 212. In the depicted embodiment, the dummy gate stacks 220 in the first region 230A has a first gate pitch P1, and the dummy gate stacks 220 in the second region 230B has a second gate pitch P2. Gate pitch refers to a distance from a sidewall (e.g., as depicted) or a center line of a gate structure (e.g., a dummy gate stack 220) to a corresponding sidewall or center line of a neighboring gate structure. The first gate pitch P1 and the second gate pitch P2 are along the X direction. P1 and P2 may be in a range of about 30 nm to about 70 nm. In some embodiments, P2 is greater than P1. The dummy gate stacks 220 in the first region 230A and in the second region 230B may have a similar width W1 in the X direction as depicted. W1 may be about 2 nm to about 16 nm. A trench 236A is formed between adjacent dummy gate stacks 220 in the first region 230A and a trench 236B is formed between adjacent dummy gate stacks 220 in the second region 230B. A distance between opposing sidewalls of the second gate spacer layer 228 in the first region 230A is D1 along the X direction, and a distance between opposing sidewalls of the second gate spacer layer 228 in the second region 230B is D2 along the X direction. In some embodiments, D2 is greater than D1. In some embodiments, a total thickness T1 of the first gate spacer layer 226 and the second gate spacer layer 228 in the first region 230A is about 7 nm to about 15 nm. In some embodiments, a total thickness T2 of the first gate spacer layer 226 and the second gate spacer layer 228 in the second region 230B is about 7 nm to about 15 nm. T2 may be equal to or greater than T1. In some embodiments, T2 is greater than T1 because more materials of the gate spacer layers may be deposited on surfaces in a region having a greater gate pitch in a deposition process.

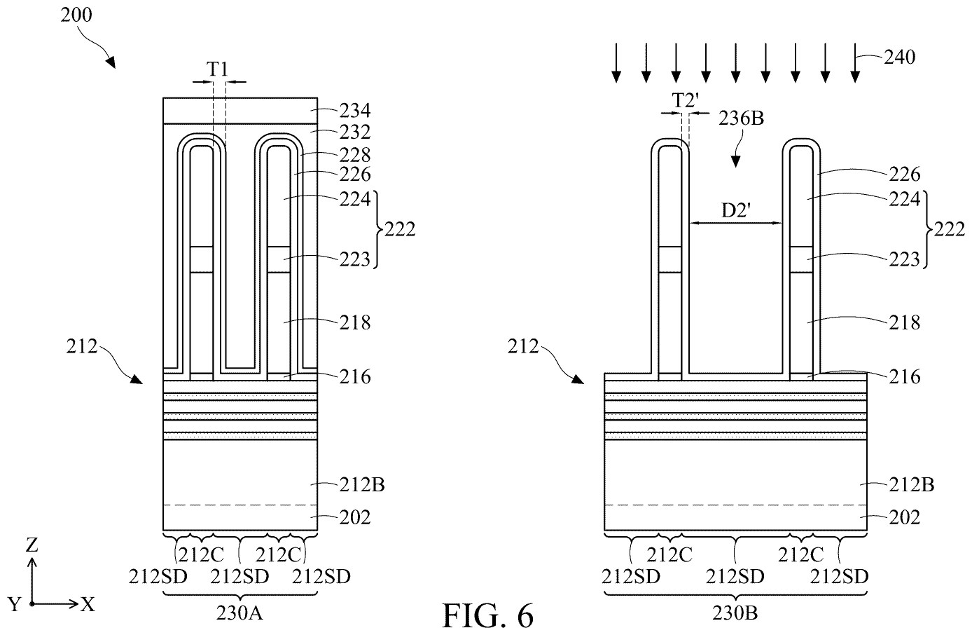

Referring to FIGS. 1 and 6, method 100 includes a block 112 where the second gate spacer layer 228 in the second region 230B is trimmed or removed, thereby enlarging the trench 236B. Operations at block 112 may include forming a mask layer 232 over the first region 230A while exposing the second region 230B, performing an etching process 240 to the second gate spacer layer 228 in the second region 230B, and removing the mask layer 232 from the first region 230A.

Forming the mask layer 232 over the first region 230A while exposing the second region 230B may include depositing a mask material over the first region 230A and the second region 230B, forming a patterned photoresist layer 234 over the mask material in the first region 230A but not the second region 230B (FIG. 6), and etching the mask material in the second region 230B using the patterned photoresist layer 234 as an etch mask.

In some embodiments, the mask material includes a bottom antireflective coating (BARC) material and provides a platform for photoresist coating and photoresist patterning. The BARC material may include silicon oxynitride (SiON), silicon oxycarbide, a polymer, or other suitable materials. In an embodiment, the mask material is formed by any suitable process, such as CVD, or spin coating a BARC material over the second gate spacer layer 228, and baking the BARC material to cause cross-linking within the BARC material. After forming the mask material, a patterned photoresist layer 234 is formed over the mask material. In an example process, a photoresist layer may be blanketly deposited over the structure 200, including over the mask material in the first region 230A and the second region 230B. The photoresist layer is then exposed to radiation going through or reflected from a mask, baked in a post-bake process, and developed in a developer solution to form the patterned photoresist layer 234, as represented in FIG. 6. In this illustrated embodiment, the patterned photoresist layer 234 is formed in the first region 230A and is not formed in the second region 230B. An etching process is then performed to recess the mask material while using the patterned photoresist layer 234 as an etch mask. The etching process may include an isotropic etching process or anisotropic etching process. The etching process may include use of a dry etch process. The dry etch process may include use of plasma of argon (Ar), oxygen (O₂), nitrogen (N₂), hydrogen (H₂), or a combination thereof. After removing the mask material from the area (e.g., the second region 230B) not covered by the patterned photoresist layer 234, the remaining mask material in the first region 230A becomes the mask layer 232. The patterned photoresist layer 234 may be selectively removed. In some cases, the patterned photoresist layer 234 may be removed during or after the etching process. Upon completion of the etching process, the second gate spacer layer 228 in the second region 230B may be exposed.

In some embodiments, the etching process 240 is then performed to trim or remove the second gate spacer layer 228 in the second region 230B. In the depicted embodiment, the trench 236B is enlarged compared to the trench 236B in FIG. 5. A distance between the opposing sidewalls of the first gate spacer layer 226 in the second region 230B is D2′ along the X direction. D2′ is greater than D2, and the difference is about twice a thickness of the second gate spacer layer 228 as in FIG. 5. Thus, source/drain recesses (to be described) to be formed in the source/drain regions 212SD in the second region 230B may be widen, and source/drain features (to be described) to be formed in the source/drain recesses may have increased volumes. In some embodiments, the etching process 240 includes dry chemical etching, remote plasma etching, wet etching, other applicable technique, and/or a combination thereof. In some embodiments, the etchants used in the etching process 240 include CF₄ or dilute HF. In some embodiments, the etching process 240 stops when the first gate spacer layer 226 is exposed. In some embodiments, the etching selectivity between the first gate spacer layer 226 and the second gate spacer layer 228 is relatively high, and the first gate spacer layer 226 may act as an etch stop layer for the etching process 240. In some embodiments, the etching process 240 stops at surfaces of the first gate spacer layer 226 by controlling the etching time. Upon completion of the etching process 240, a total thickness of the gate spacer layers in the second region 230B is reduced to T2′. T2′ is less than T2. A difference between T2 and T2′ is equal to or less than about 2 nm. In some embodiments, T2′ is less than T1.

After the etching process 240, the mask layer 232 is removed from the first region 230A. One or more etching processes may be performed to selectively remove the mask layer 232 without substantially etching other features (e.g., the first gate spacer layer 226, the second gate spacer layer 228). The mask layer 232 may be removed using an ashing process or a dry etch process that includes use of plasma of argon (Ar), oxygen (O₂), nitrogen (N₂), hydrogen (H₂), or a combination thereof. A cleaning process may be performed to clean surfaces of the structure 200 after the etching process 240. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide, SPM (a sulfuric peroxide mixture), and/or hydrofluoric acid for oxide removal.

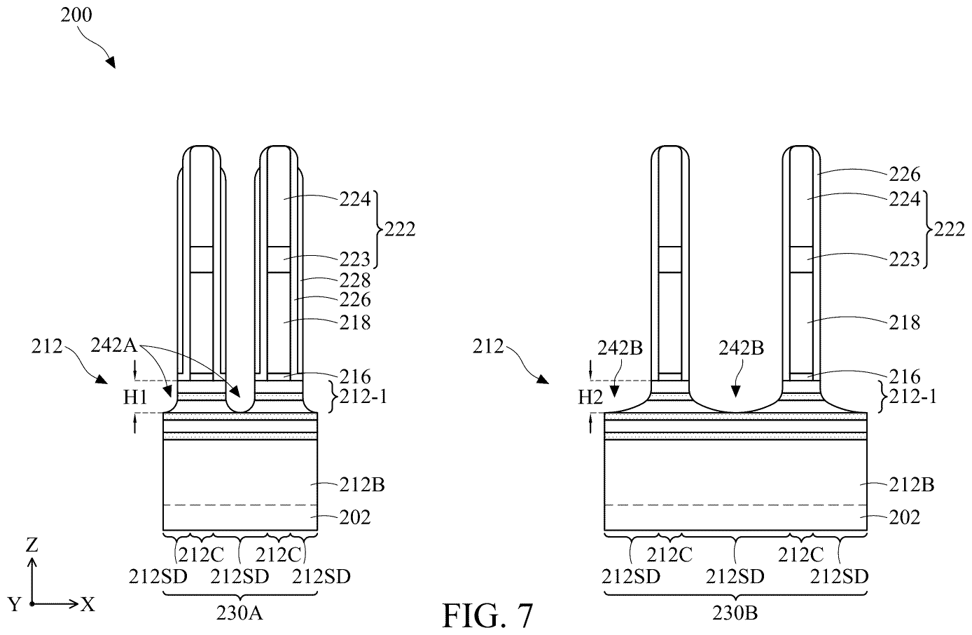

Referring to FIGS. 1 and 7, method 100 includes a block 114 where a first etching process is performed to the source/drain regions 212SD to form initial recesses 242A (also referred to as shallow recesses 242A) in the first region 230A and initial recesses 242B (also referred to as shallow recesses 242B) in the second region 230B. In some embodiments, the source/drain regions 212SD are anisotropically recessed. The anisotropic etch may include a dry etch or a suitable etch process that etches the first gate spacer layer 226 and the second gate spacer layer 228 in the first region 230A, the first gate spacer layer 226 in the second region 230B, and top portions 212-1 of the fin-shaped structures 212 in the source/drain regions 212SD. The initial recesses 242A and 242B may have a depth H1 and a depth H2, respectively. H2 may be equal to or greater than H1 because of loading effect. An example dry etch process for block 114 may implement first etchants including an oxygen-containing gas, a fluorine-containing gas (e.g., CF₄, SF₆, CH₂F₂, CHF₃, C₄F₈, and/or C₂F₆), a chlorine-containing gas (e.g., Cl₂, CHCl₃, CCl₄, and/or BCl₃), a bromine-containing gas (e.g., HBr and/or CHBr₃), an iodine-containing gas, other suitable gases and/or plasmas, and/or combinations thereof. In some embodiments, the first etching process includes a first step to break through (e.g., etch) the gate spacer layer(s), and a second step to etch the top portions 212-1 of the fin-shaped structures 212. In some embodiments, an etchant gas in the first step includes fluoromethane (CH₃F) and/or CHF₃. In some embodiments, an etchant gas in the second step includes Cl₂ and/or hydrogen bromide (HBr). A temperature of the second step may be about 20 °C to about 60 °C. A pressure of the second step may be about 30 mTorr to about 150 mTorr. A power of about 100 W to about 500 W may be applied in the second step. Upon completion of the first etching process, surfaces of the top portion 212-1 of the fin-shaped structures 212 in the first region 230A and the second region 230B are exposed in the initial recesses 242A and 242B.

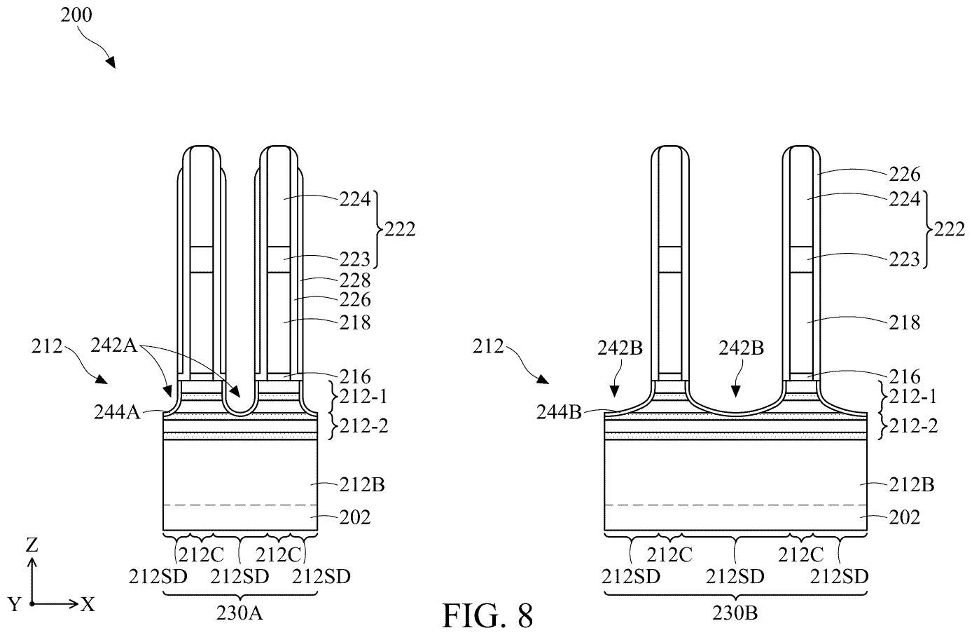

Referring to FIGS. 1 and 8, method 100 includes a block 116 where a nitridation process is performed to the structure 200, thereby forming a nitridation layer 244A and 244B on the exposed surfaces of the top portion 212-1 of the fin-shaped structures 212 in the first region 230A and the second region 230B, respectively. Operations at block 116 are optional. Optional blocks may be illustrated in dashed rectangles with rounded corners. The nitridation process may be performed in a different chamber from the operations at blocks 114 and 118. In some embodiments, performing the nitridation process includes flowing a nitrogen-containing gas over the structure 200, including in the initial recesses 242A and 242B. In some embodiments, the nitrogen-containing gas includes nitrogen gas. Performing the nitridation process may be at a pressure of about 150 mTorr to about 300 mTorr and a temperature of about 40 °C to about 60 °C. In some embodiments, a flow rate of the nitrogen-containing gas may be about 30 standard cubic centimeters per minute (sccm) to about 150 sccm. Performing the nitridation process may include applying a power of about 100 W to about 500 W. Nitrogen in the nitrogen-containing gas may diffuse into the exposed surfaces of the top portions 212-1 of the fin-shaped structures 212 to form the nitridation layers 244A and 244B. The nitridation layers 244A and 244B may include a nitride (e.g., SiN). The nitridation layers 244A and 244B may protect the top portion 212-1 of the fin-shaped structures 212 from being laterally recessed in a second etching process (to be described). In some embodiments, because of different gate pitches, more nitrogen-containing gas may flow into the initial recess 242B than the initial recess 242A, thus, the nitridation layer 244B is thicker than the nitridation layer 244A. The nitridation layers 244A and 244B may have a thickness of about 2 Å to about 10 Å. If the nitridation layer is too thick (e.g., greater than about 10 Å) or the flow rate of the nitrogen-containing gas is too high (e.g., greater than about 150 sccm), protection provided by the nitridation layers 244A and 244B may be too much, thus following lateral etching to the top portions 212-1 may be too small.

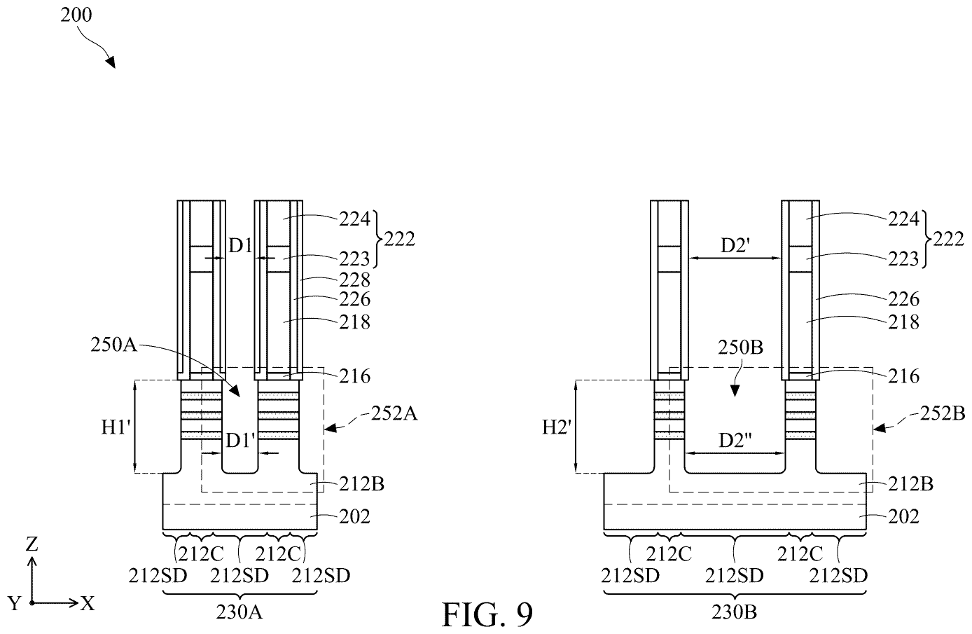

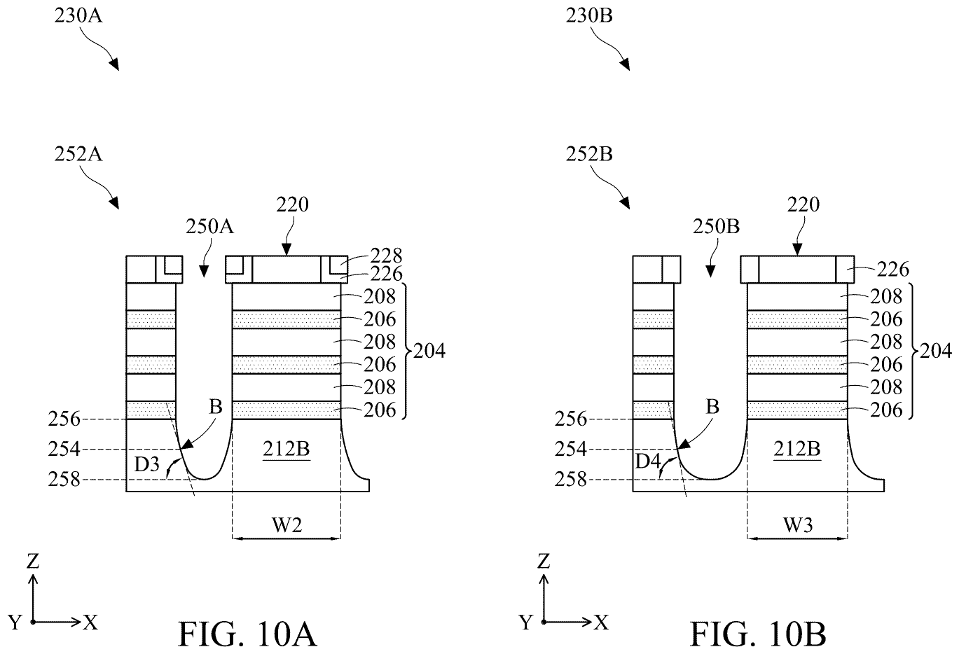

Referring to FIGS. 1 and 9-10B, method 100 includes a block 118 where the second etching process is performed to extend the initial recesses 242A and 242B to form source/drain recesses 250A and 250B, respectively. FIGS. 10A and 10B illustrate enlarged views of portions 252A and 252B of the structure 200 as in FIG. 9, respectively.

In some embodiments, the source/drain regions 212SD are further anisotropically recessed in the second etching process. The anisotropic etch may include a dry etch or a suitable etch process that etches bottom portions 212-2 of the fin-shaped structures 212 in the source/drain regions 212SD, and a portion of the base fin structures 212B. An example dry etch process for block 118 may implement second etchants selected from similar gas(es) and/or plasmas, and/or combinations thereof, as described above for the first etching process (e.g., the second step in the first etching process). Operation conditions (e.g., temperature, pressure, power) of the second etching process may be similar to those described above for the second step in the first etching process. Time duration of the second etching process may be less than time duration of the first etching process.

The anisotropic etch may have side effects on exposed sidewalls in the source/drain recesses 250A and 250B. The side effects may laterally etch the nitridation layers 244A and 244B, as well as the channel layers 208 and the sacrificial layers 206 after the nitridation layers 244A and 244B thereon are removed. In some embodiments, the nitridation layers 244A and 244B are removed during the anisotropic etch. The nitridation layers 244A and 244B may reduce lateral etching to the top portions 212-1 of the fin-shaped structures 212. Because of the side effects, sidewalls of the source/drain recesses 250A may be laterally recessed from the second gate spacer layer 228 in the first region 230A. Similarly, sidewalls of the source/drain recesses 250B may be laterally recessed from the first gate spacer layer 226 in the second region 230B. In some embodiments, the source/drain recess 250A has a width D1′ and a depth H1′. D1′ is greater than D1. In some embodiments, D1′ is greater than D1 by about 1 nm to about 8 nm. A ratio of H1 (as in FIG. 7) to H1′ may be about ½ to about ⅓. In some embodiments, the source/drain recess 250B has a width D2″ and a depth H2′. D2″ is greater than D2′. In some embodiments, D2″ is greater than D2′ by about 1 nm to about 8 nm. A ratio of H2 (as in FIG. 7) to H2′ may be about ½ to about ⅓. In some embodiments, H2′ is greater than H1′. H2′ may be greater than H1′ by 0 nm to about 12 nm.

Referring to FIGS. 10A and 10B, the channel layers 208 in the first region 230A may have a channel width W2, and the channel layers 208 in the second region 230B may have a channel width W3. W3 may be less than W2. In some embodiments, W3 is equal to or less than W2 by 0 nm to about 3 nm. By having the disclosed W3 and W2, junction overlap of the source/drain features (to be described) in the second region 230B may be decreased, thus effective parasitic capacitance (e.g., between the source/drain feature and an adjacent gate structure) of the structure 200 may be reduced, and current and speed of the structure 200 may be increased. In some embodiments, both the first source/drain recess 250A and the second source/drain recess 250B have a U-shaped profile. In the depicted embodiment, at a middle level 254 between a top surface level 256 of the base fin structure 212B and a bottom surface level 258 of the source/drain recess 250A or 250B, a tangent line at a point B to the sidewall of the source/drain recess 250A or 250B has an angle D3 or D4, respectively, with respect to a horizontal line. D3 and D4 may each be about 45 degree to about 89 degree. D3 may be smaller than D4. In some embodiments, the first source/drain recess 250A has a V-shaped profile and the second source/drain recess 250B has a U-shaped profile. In such embodiments, D3 may be about 20 degree to about 45 degree. The channel widths differences and the profiles of the source/drain region may be detected by a tool, such as a transmission electron microscope (TEM).

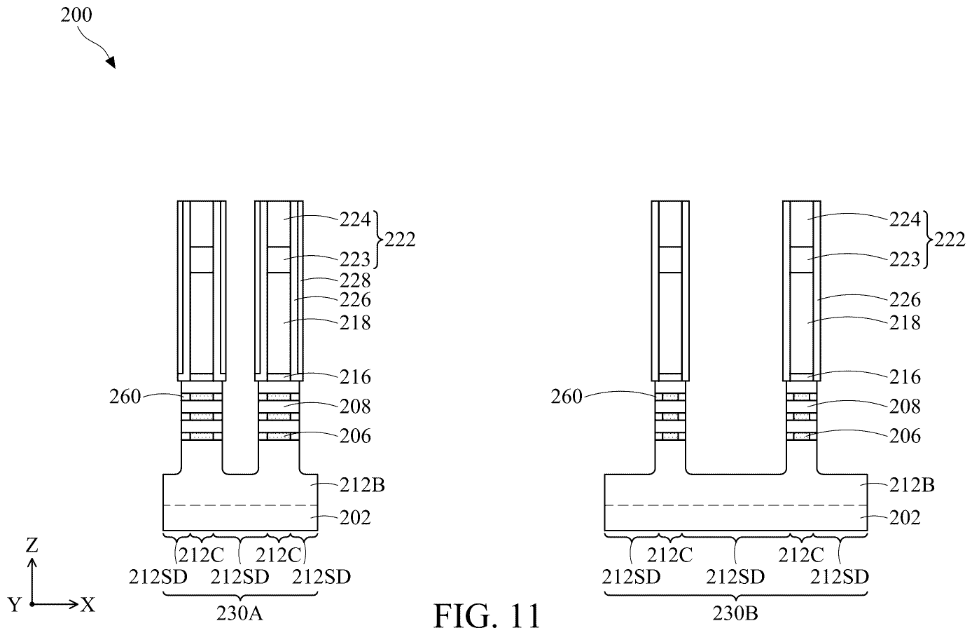

Referring to FIGS. 1 and 11, method 100 includes a block 120 where inner spacer features 260 are formed between the channel layers 208. Forming the inner spacer features 260 may include forming inner spacer recesses and forming the inner spacer features 260 in the inner spacer recesses. Block 120 is optional.

The sacrificial layers 206 may be selectively and partially recessed to form inner spacer recesses (the space where the inner spacer features 260 are in FIG. 11). The inner spacer recesses may have a rectangular profile as illustrated. Alternatively, the inner spacer recesses may have a curved (e.g., convex) profile bending away from the source/drain recesses 250A or 250B. The different compositions allow the sacrificial layers 206 exposed in the source/drain recesses 250A or 250B to be selectively and partially recessed to form inner spacer recesses while the exposed channel layers 208 are substantially unetched. In an embodiment where the channel layers 208 consist essentially of Si and the sacrificial layers 206 consist essentially of SiGe, the selective recess of the sacrificial layers 206 may include a SiGe oxidation process followed by a SiGe oxide removal. In those embodiments, the SiGe oxidation process may include use of ozone. In some embodiments, the selective recess may be a selective isotropic etching process (e.g., a selective dry etching process or a selective wet etching process), and the extent the sacrificial layers 206 are recessed is controlled by duration of the etching process. In some embodiments, the selective dry etching process may include use of one or more fluorine-based etchants, such as fluorine gas or hydrofluorocarbons. The inner spacer recesses may extend inward along the X direction from the source/drain recesses 250A or 250B. In some embodiments, the selective wet etching process may include a hydro fluoride (HF) or NH₄OH etchant.

The formation of the inner spacer features 260 may include the deposition of an inner spacer layer over exposed surfaces of the source/drain recesses 250A and 250B, including filling the inner spacer recesses. In some embodiments, the inner spacer layer may include silicon carbonitride (SiCN), silicon oxycarbonitride (SiOCN), silicon nitride (SiN), silicon oxycarbide (SiOC), or silicon oxynitride (SiON). In some implementations, the inner spacer layer may be deposited using CVD or ALD. Subsequently, the inner spacer layer is etched back to form inner spacer features 260 in the inner spacer recesses. In some embodiments, the etching back of the inner spacer layer may include use of a dry etching process, such as a reactive ion etching (RIE) process that is aided by plasma. An example dry etching process may include use of boron trichloride (BCl₃), chlorine (Cl₂), hydrogen chloride (HCl), methane (CH₄), nitrogen trifluoride (NF₃), carbon tetrafluoride (CF₄), sulfur hexafluoride (SF₆), nitrogen (N₂), or a combination thereof. In some embodiments, the inner spacer features 260 substantially remain under the gate spacer layers 226 and/or 228 without extending to a position directly under the dummy gate stack 220. Alternatively, the inner spacer features 260 may laterally extend to a position directly under the dummy gate stack 220. In such embodiments, the parasitic capacitance between the source/drain feature and the adjacent gate structure may be reduced.

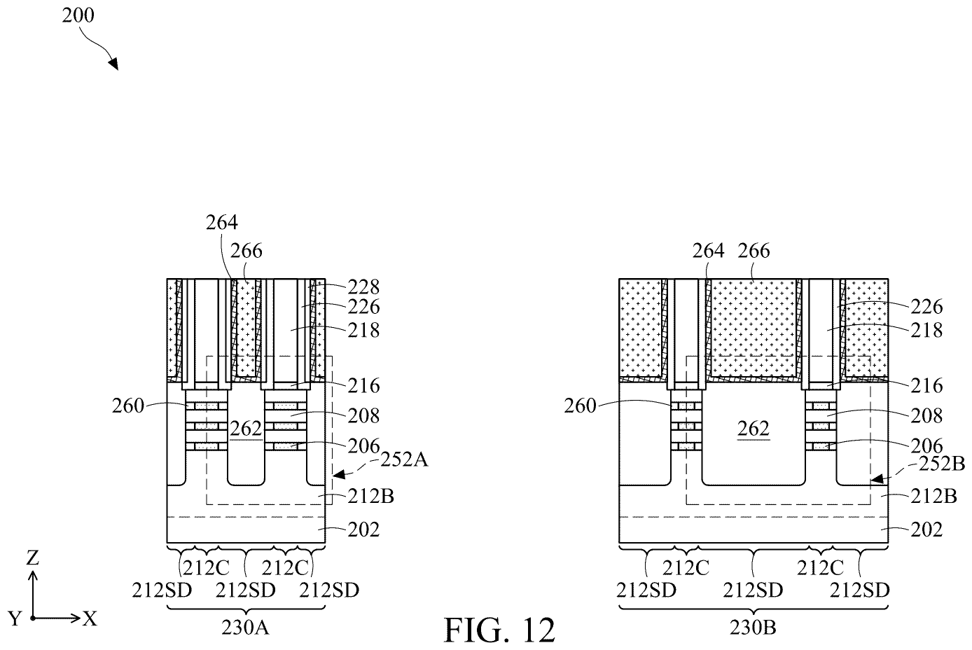

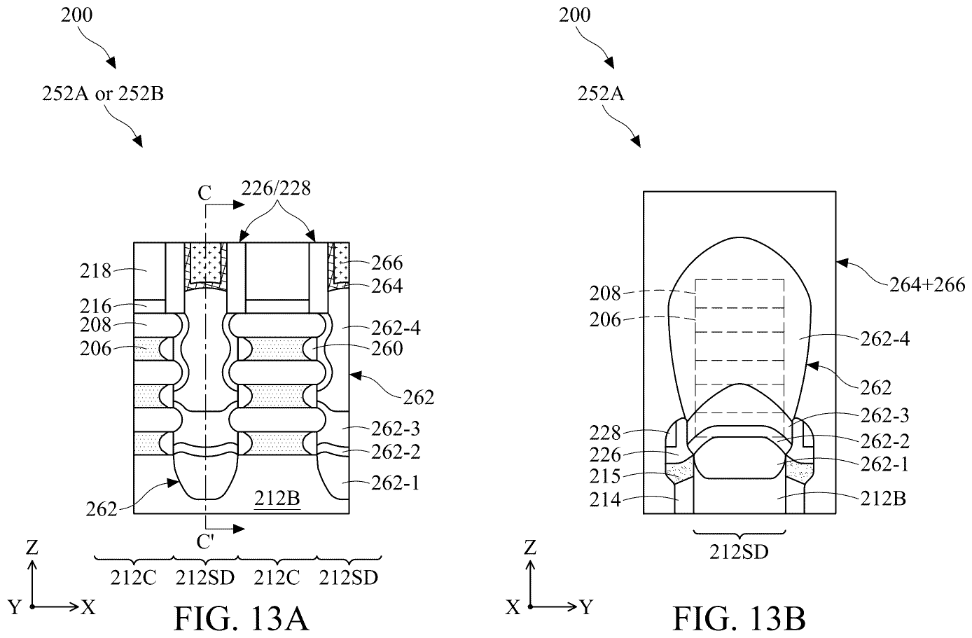

Referring to FIGS. 1 and 12-13B, method 100 includes a block 122 where source/drain structures 262 are formed in the source/drain recesses 250A and 250B. FIG. 13A illustrates an enlarged view of the portion 252A or 252B of the structure 200 as in FIG. 12. FIG. 13B illustrates a fragmentary cross-sectional view of the structure 200 taken along line C-C′ as in FIG. 13A. While not explicitly shown, before any of the epitaxial layers are formed, method 100 may include a cleaning process to clean surfaces of the structure 200. The cleaning process may include a dry clean, a wet clean, or a combination thereof. In some examples, the wet clean may include use of a mixture of deionized (DI) water, ammonium hydroxide, and hydrogen peroxide, a mixture of DI water, hydrochloric acid, and hydrogen peroxide, SPM (a sulfuric peroxide mixture), and/or hydrofluoric acid for oxide removal. The dry clean process may include helium (He) and hydrogen (H₂) treatment.

In some embodiments, the source/drain structures 262 each include multiple layers (e.g., as depicted in FIGS. 13A and 13B). The source/drain structures 262 may each include a source/drain feature and optionally an interposing layer below the source/drain feature. As illustrated in FIG. 13B, in some embodiments, in the Y-Z plane each source/drain structures 262 may include a portion overhanging the isolation structure 214 and the protecting layer 215.

In some embodiments, an interposing feature is deposited in the bottom of the source/drain recesses 250A and 250B. The interposing feature may include a first interposing layer 262-1, a second interposing layer 262-2, or both. In some embodiments, the first interposing layer 262-1 is a buffer epitaxial layer epitaxially grown from the top surface of the base fin structure 212B. By way of example, epitaxial growth of the first interposing layer 262-1 may be performed by VPE, ultra-high vacuum CVD (UHV-CVD), MBE, and/or other suitable epitaxial grow processes. In some embodiments, the first interposing layer 262-1 includes the same material as the substrate 202, such as silicon. In some alternative embodiments, the first interposing layer 262-1 includes a different semiconductor material other than silicon, such as SiGe, SiSn, or other suitable semiconductor material. In some embodiments, the first interposing layer 262-1 is dopant-free, where for example, no intentional doping is performed during the epitaxial growth process. As a comparison, in one instance, the substrate 202 is lightly doped and has a higher doping concentration than the first interposing layer 262-1. The first interposing layer 262-1 provides a high resistance path from the source/drain feature to the substrate, such that the leakage current in the substrate 202 is suppressed. Notably, the formation of the first interposing layer 262-1 may be optional. That is, the formation of the first interposing layer 262-1 may be omitted, and the first interposing layer 262-1 may not exist in the final structure, in some embodiments.

A second interposing layer 262-2 may be formed over the first interposing layer 262-1 (or on the substrate 202 if the formation of the first interposing layer 262-1 is omitted). Because the second interposing layer 262-2 may interface source/drain features and oxygen content may oxidize source/drain features, the second interposing layer 262-2 may be formed of an oxygen-free dielectric material, such as a nitride (e.g., silicon nitride). In an example process, a chlorine-containing silicon nitride layer is deposited over the source/drain recesses 250A and 250B, including over a top surface of the first interposing layer 262-1. The chlorine-containing silicon nitride layer may be deposited using ammonia (NH₃) and a chlorine-containing silicon precursor, such as silicon tetrachloride (SiCl₄), dichlorodisilane (Si₂H₄Cl₂), dichlorosilane (SiH₂Cl₂), or hexachlorodisilane (Si₂Cl₆). The chlorine-containing silicon nitride layer may be deposited using plasma-enhanced atomic layer deposition (PEALD) or thermal ALD. A directional plasma treatment process is then performed to remove chlorine from a bottom portion of the chlorine-containing silicon nitride layer. In some embodiments, the directional plasma treatment may include use of an argon (Ar) plasma, a nitrogen (N₂) plasma, and/or a hydrogen (H₂) plasma. After the directional plasma treatment, a dry etching process using fluorine-containing etchant (e.g., trifluoromethane (CHF₃), nitrogen trifluoride (NF₃), hydrogen (H₂), ammonia (NH₃), carbon tetrafluoride (CF₄), or sulfur hexafluoride (SF₆)) may be performed. Because the dry etching process etches the chlorine-containing silicon nitride along sidewalls faster than it does relatively to chlorine-free silicon nitride layer at the bottom of the source/drain recesses 250A and 250B, the second interposing layer 262-2 may be formed over the first interposing layer 262-1. In some other embodiments, the second interposing layer 262-2 includes silicon boride (SiB) or Si with doped boron. In such embodiments, the second interposing layer 262-2 may be formed by vapor-phase epitaxy (VPE), ultra-high vacuum CVD, or molecular beam epitaxy (MBE), and may be in-situ doped during the epitaxial process. The second interposing layer 262-2 and the first interposing layer 262-1 may be sandwiched between the gate spacer layers 226 and 228 along the Y direction in the source/drain region 212SD. Notably, the formation of the second interposing layer 262-2 may be optional. That is, the formation of the second interposing layer 262-2 may be omitted, and the second interposing layer 262-2 may not exist in the final structure, in some embodiments.

The source/drain features may include multiple layers (e.g., the epitaxial layers 262-3 and 262-4) and are epitaxially grown from the exposed semiconductor surfaces in the source/drain recesses 250A and 250B, including from the sidewalls of the channel layers 208. The source/drain feature may be n-type or p-type. When the source/drain feature is n-type, the source/drain feature may include silicon (Si) and an n-type dopant, such as phosphorus (P), arsenic (As), antimony (Sb), or a combination thereof. When the source/drain feature is p-type, the source/drain feature may include silicon germanium (SiGe) and a p-type dopant, such as boron (B), boron difluoride (BF₂), or a combination thereof. In some embodiments, the source/drain feature includes a lightly doped epitaxial layer 262-3 over the sidewalls of the channel layers 208 and a heavily doped epitaxial layer 262-4 over the lightly doped epitaxial layer 262-3. The lightly doped epitaxial layer 262-3 includes smaller dopant concentration and impurity concentration to reduce crystalline defects. The heavily doped epitaxial layer 262-4 accounts for a majority of the volume to reduce resistance. The source/drain feature(s) may refer to a source or a drain, individually or collectively dependent upon the context. The source/drain feature may be formed using vapor-phase epitaxy (VPE), ultra-high vacuum CVD (UHV-CVD), or molecular beam epitaxy (MBE). Doping of the source/drain features may be achieved with in-situ doping.

Still referring to FIGS. 1 and 12-13B, method 100 includes a block 124 where a contact etch stop layer (CESL) 264 is formed over the source/drain structures 262 and an interlayer dielectric (ILD) layer 266 is formed over the CESL 264.

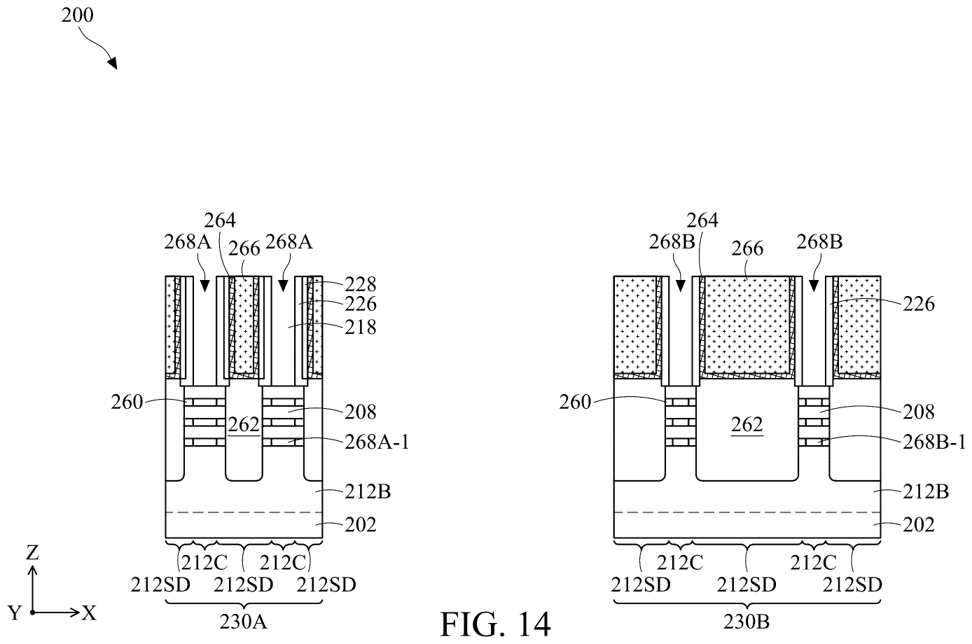

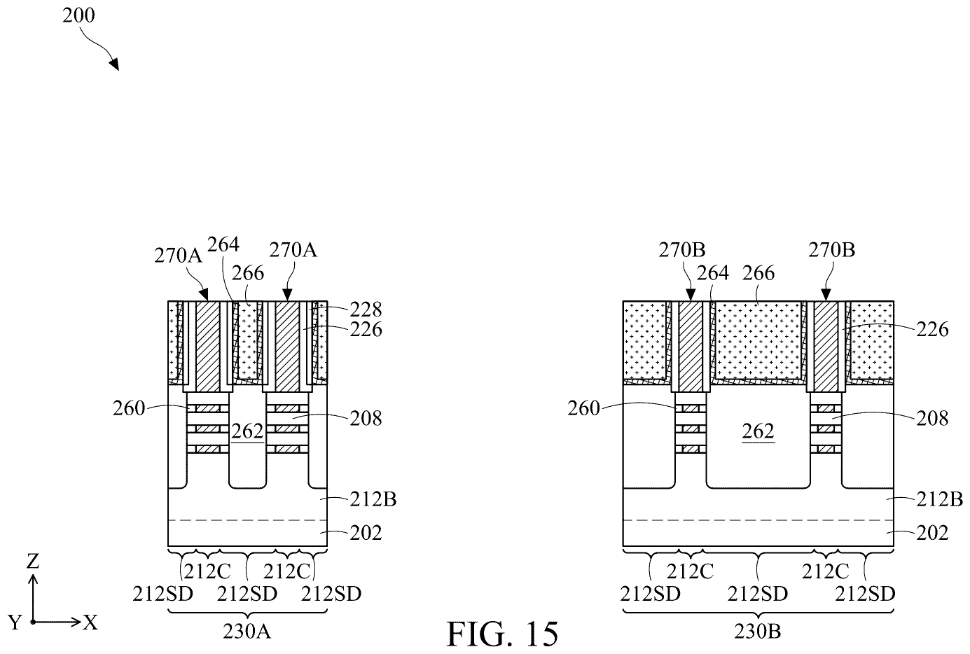

As shown in FIGS. 14-15, the CESL 264 is deposited over the source/drain structures 262. As shown in FIG. 13B, the gate spacer layers 226 and 228 in the source/drain region 212SD are also covered by the CESL 264. The CESL 264 may include silicon nitride or aluminum nitride. In some implementations, the CESL 264 may be deposited using CVD or ALD. The ILD layer 266 is then deposited over the CESL 264. In some embodiments, the ILD layer 266 includes materials such as an oxide-based dielectric material, SiOx, SiON, SiC, tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 266 may be deposited using CVD, flowable CVD (FCVD), spin-on coating, or a suitable deposition technique. After the deposition of the ILD layer 266, the structure 200 may be planarized by a planarization process to remove the gate-top hard mask layer 222 and expose the dummy electrode layer 218. For example, the planarization process may include a chemical mechanical planarization (CMP) process. After the planarization, top surfaces of the CESL 264, the ILD layer 266, the gate spacer layers 226 and 228, and the dummy electrode layer 218 are coplanar.

Referring to FIGS. 1 and 14, method 100 includes a block 126 where the dummy gate stacks 220 and subsequently the sacrificial layers 206 are selectively removed. The exposure of the dummy gate stacks 220 at the conclusion of operations at block 124 allows the removal thereof. The removal of the dummy gate stacks 220 may include one or more etching processes that are selective to the materials of the dummy gate stacks 220. For example, the removal of the dummy gate stacks 220 may be performed using a selective wet etch, a selective dry etch, or a combination thereof that is selective to the dummy gate stacks 220. The removal of the dummy gate stacks 220 forms gate trenches 268A and 268B that expose the stack of the channel layers 208 and the sacrificial layers 206. After the removal of the dummy gate stacks 220, the sacrificial layers 206 in the channel regions 212C are exposed and subsequently removed in a separate etching process. For example, a selective wet etching process or a selective dry etching process may be performed to remove the sacrificial layers 206. An example selective wet etching process may include use of diluted hydrofluoric acid (DHF) or a mixture of hydrofluoric acid (HF) and ammonium fluoride (NH₄F). An example selective dry etching process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. After the removal of the sacrificial layers 206, the channel layers 208 are released as channel members (also referred to as channel members 208 hereinafter). Openings 268A-1 and 268B-1 may be formed between the channel members 208 and between a bottommost channel member 208 and the base fin structure 212B as a part of the gate trenches 268A and 268B, respectively.

Referring to FIGS. 1 and 15, method 100 includes a block 128 where gate structures 270A and 270B are formed in the gate trenches 268A and 268B, respectively, to wrap around each of released as channel members 208.

After the release of the channel members 208, the gate structures 270A and 270B are formed in the first region 230A and the second region 230B, respectively, to wrap around each of the channel members 208. Although not explicitly depicted, the gate structures 270A and 270B each include an interfacial layer interfacing the channel members 208 and the base fin structure 212B in the channel region 212C, a gate dielectric layer over the interfacial layer, and a gate electrode layer over the gate dielectric layer. The interfacial layer may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may include a high-k dielectric material, such as hafnium oxide. Alternatively, the gate dielectric layer may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. In some embodiments, a thickness of the gate dielectric layer is less than a thickness of the first gate spacer layer 226 or a thickness of the second gate spacer layer 228. In some embodiments, a dielectric constant of the gate dielectric layer is greater than a dielectric constant of the first gate spacer layer 226 or a dielectric constant of the second gate spacer layer 228. The gate dielectric layer may be formed by ALD, physical vapor deposition (PVD), CVD, oxidation, and/or other suitable methods.

The gate electrode layer of the gate structures 270A and 270B may include a single layer or alternatively a multi-layer structure, such as various combinations of a metal layer with a selected work function to enhance the device performance (work function metal layer), a liner layer, a wetting layer, an adhesion layer, a metal alloy or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof. In various embodiments, the gate electrode layer may be formed by ALD, PVD, CVD, e-beam evaporation, or other suitable process. In various embodiments, a CMP process may be performed to remove excessive metal, thereby providing a substantially planar top surface of the gate structure. The gate structures 270A and 270B includes portions that interpose between channel members 208 in the channel region 212C.

The semiconductor device 200 may undergo further processing to form various features and regions known in the art. For example, subsequent processing may form additional interlayer dielectric (ILD) layer(s), contacts/vias/lines and multilayers interconnect features (e.g., metal layers and interlayer dielectrics) over the substrate 202, configured to connect the various features to form a functional circuit that may include one or more devices including the semiconductor device 200. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure.

Referring to FIG. 16, a method 300 is illustrated herein. Compared to method 100, method 300 includes blocks 319 and 320 instead of block 120, and includes a block 326 instead of block 126. FIG. 17 illustrates a fragmentary cross-sectional view of a structure 400 at various fabrication stages associated with the method of FIG. 16.

In some embodiments, referring to FIGS. 16-17, after performing the second etching process at block 118, method 300 includes a block 319 where the sacrificial layers 206 are replaced by dielectric sacrificial layers 272. Operations at block 319 may include removing the sacrificial layers 206 to release the channel layers 208 as channel members 208, and forming the dielectric sacrificial layers 272.

In some embodiments, referring to FIG. 9, after the formation of the source/drain recesses 250A and 250B, the sacrificial layers 206 interleaving the channel layers 208 in the channel regions 212C are selectively removed. The selective removal of the sacrificial layers 206 releases the channel layers 208 (shown in FIG. 9) to form channel members 208. The selective removal of the sacrificial layers 206 forms spaces between adjacent channel members 208 and between the bottommost channel member 208 and the fin base structure 212B. The selective removal of the sacrificial layers 206 may be implemented by selective dry etch, selective wet etch, or other selective etch processes. An example selective dry etching process may include use of one or more fluorine-based etchants, such as fluorine gas or hydrofluorocarbons. An example selective wet etching process may include an APM etch (e.g., ammonia hydroxide-hydrogen peroxide-water mixture). Depending on the design, the channel members 208 may take form of nanowires, nanosheets, or other nanostructures.

In some embodiments, a dielectric material for the dielectric sacrificial layers 272 is then deposited around the channel members 208 and over the source/drain recesses 250A and 250B in the first region 230A and the second region 230B, respectively. The dielectric material may include an oxide, a nitride, a carbide, or a combination thereof. Examples of the dielectric material may include silicon oxide, SiCO, SiN, SiCN, and aluminum oxide (e.g., Al₂O₃). In some embodiments, the dielectric material includes silicon oxide and/or aluminum oxide. The dielectric material may be deposited using plasma enhanced chemical vapor deposition (PECVD), an flowable CVD (FCVD), PEALD, ALD, or a rapid thermal oxidation (RTO) process. The dielectric material may fill the spaces between adjacent channel members 208 and between the bottommost channel member 208 and the fin base structure 212B, and covers end sidewalls of the channel members 208. Additionally, the dielectric material is in direct contact with a sidewall of the gate spacer layers 226 and/or 228 and a top surface of the substrate 202 or the base fin structure 212B. In some embodiments, excess dielectric material on the sidewalls of the gate spacer layers 226 and 228, on the sidewalls of the channel members 208, and in the source/drain regions 212SD are removed, thereby leaving the dielectric material in the spaces between adjacent channel members 208 and between the bottommost channel member 208 and the fin base structure 212B to form the dielectric sacrificial layers 272 as in FIG. 17. The removing of the excess dielectric material may use a selective wet etch process or a selective dry etch process, such that the gate spacer layers 226 and 228, the dummy gate stacks 220, the exposed portion of the substrate 202 or the base fin structure 212B, and the channel members 208 are substantially unetched. An example selective dry etching process may include use of carbon tetrafluoride (CF₄), nitrogen trifluoride (NF₃), hydrogen (H₂), or a mixture thereof. An example selective wet etching process may include use of hydrofluoric acid, ammonium fluoride, or a mixture thereof.

In some embodiments, after forming the dielectric sacrificial layers 272, method 300 includes an optional block 320 where inner spacer features 260 are formed between adjacent channel members 208 and adjacent to the dielectric sacrificial layers 272. In some embodiments, the dielectric sacrificial layers 272 (as in FIG. 17) are selectively and partially recessed to form inner spacer recesses similar to those described above at block 120, and the inner spacer features 260 are formed in the inner spacer recesses. The gate spacer layers 226 and 228, the dummy gate stacks 220, the exposed portion of the substrate 202 or the base fin structure 212B, and the channel members 208 are substantially unetched during the recessing to the dielectric sacrificial layers 272. In an embodiment where the channel members 208 consist essentially of silicon (Si) and the dielectric sacrificial layer 272 is formed of silicon oxide, the selective recess of the dielectric sacrificial layer 272 may be performed using a selective wet etch process or a selective dry etch process, such as those described above for the removing of the excess dielectric material. Forming the inner spacer features 260 in the inner spacer recesses may be similar to those described above at block 120.

In some embodiments, after forming the CESL 264 and the ILD layer 266, method 300 includes a block 326 where the dummy gate stacks 220 and the dielectric sacrificial layers 272 are removed to form the gate trenches 268A and 268B. The removal of the dummy gate stacks 220 is similar to those described at block 126. After the removal of the dummy gate stacks 220, sidewalls of the channel members 208 and the dielectric sacrificial layers 272 in the channel regions 212C are exposed. A separate etch process may be performed to selectively remove the dielectric sacrificial layers 272 in the channel regions 212C. For example, a selective wet etch process or a selective dry etch process may be performed to remove the dielectric sacrificial layers 272. An example selective wet etch process may include use of diluted hydrofluoric acid (DHF) or a mixture of hydrofluoric acid (HF) and, ammonium fluoride (NH₄F). An example selective dry etch process may include use of anhydrous hydrogen fluoride (HF) vapor, trifluoromethane (CHF₃), nitrogen trifluoride (NF₃), hydrogen (H₂), ammonia (NH₃), carbon tetrafluoride (CF₄), sulfur hexafluoride (SF₆), or a combination thereof. After the selective removal of the dielectric sacrificial layers 272, the channel members 208 in the channel regions 212C are once again exposed. The selective removal of the dummy gate stacks 220 and the dielectric sacrificial layers 272 forms the gate trenches 268A and 268B that include the openings 268A-1 and 268B-1 between adjacent channel members 208 in the first region 230A and the second region 230B, respectively, as depicted in FIG. 14. The structure 400 may then proceed to undergo further processes, such as operations at block 128.

FIGS. 18-19 illustrate fragmentary cross-sectional views of an alternative structure 500 at various fabrication stages associated with method 100 or method 300. Referring to FIGS. 1, 16, and 18, in some embodiments, a power in the second etching process at block 118 is reduced (e.g., to be less than about 100 W), and the source/drain recesses 250A and 250B having bowl-shaped profiles are formed. In the depicted embodiment, the sidewalls of the source/drain recesses 250A and 250B curve toward the channel layers 208 and the sacrificial layers 206. In such embodiments, the channel widths in the first region 230A and the second region 230B may be further reduced compared to the embodiments represented by FIGS. 9-10B. The channel widths in the first region 230A may be equal to or greater than the channel widths in the second region 230B at a same level (e.g., the bottommost channel layers 208) by 0 nm to about 3 nm, similar as described with respect to FIGS. 10A-10B. FIG. 19 illustrates the structure 500 after forming the gate structures 270A and 270B. As depicted, the source/drain structures 262 have similar bowl-shaped profiles as the source/drain recesses 250A and 250B. In such embodiments, inner portions of the gate structures 270A or 270B between neighboring channel layers 208 and between the bottommost channel layer 208 and the base fin structure 212B may have different width along the X direction. For example, in the gate structure 270A or 270B, a topmost inner portion is wider than a middle inner portion along the X direction, and a bottommost inner portion is wider than the middle inner portion along the X direction.

FIGS. 20-21 illustrate fragmentary cross-sectional views of an alternative structure 600 at various fabrication stages associated with method 100 or method 300. In the depicted embodiment, the structure 600 includes a first region 230A, a second region 230B, and a third region 230C. At blocks 108 and 110, the first gate spacer layer 226 and the second gate spacer layer 228 may be deposited over the first region 230A, the second region 230B, and the third region 230C. At block 112, the second gate spacer layer 228 may be removed from the second region 230B and the third region 230C.

Referring to FIGS. 1, 16, and 20, in some embodiments, method 100 and method 300 each include a block 113 where the first gate spacer layer 226 in the third region 230C is partially trimmed, thereby reducing a thickness of the first gate spacer layer 226 in the third region 230C. The trimming of the first gate spacer layer 226 in the third region 230C may use similar method as those described at block 112. For example, the trimming includes forming a patterned mask layer over the first region 230A and the second region 230B, while exposing the third region 230C, performing an etching process to the first gate spacer layer 226 in the third region 230C, and removing the patterned mask layer from the first region 230A and the second region 230B. In some embodiments, total thicknesses of the first gate spacer layer 226 and the second gate spacer layer 228 (if any) in the first region 230A, the second region 230B, and the third region 230C are T1, T2′, and T3″, respectively. In some embodiments, T1 is greater than T2′, and T2′ is greater than T3″.

Gate pitch P1 in the first region 230A, gate pitch P2 in the second region 230B, and gate pitch P3 in the third region 230C may be the same or different. In some embodiments, the dummy gate stacks 220 have similar widths along the X direction in the first region 230A, the second region 230B, and the third region 230C. In some embodiments, the gate pitches P1, P2, and P3 are the same. In some other embodiments, the gate pitch P1 is smaller than the gate pitch P2, and the gate pitch P2 is smaller than the gate pitch P3. In some embodiments, a width D5 of the first trench 236A is smaller than a width D6 of the second trench 236B. In some embodiments, the width D6 is smaller than a width D7 of a third trench 236C in the third region 230C.

The structure 600 may undergo following processes in method 100 or method 300. FIG. 21 illustrates a fragmentary cross-sectional view of the structure 600 upon completion of block 128. As illustrated in FIG. 21, the source/drain structures 262 in the first region 230A, the second region 230B, and the third region 230C may have widths D8, D9, and D10, respectively. In some embodiments, D8 is less than D9, and D9 is less than D10. In some embodiments, the channel width W2 in the first region 230A, the channel width W3 in the second region 230B, and a channel width W4 in the third region 230C along the X direction may gradually decrease (e.g., W2>W3>W4). Devices (e.g., transistors) in the first region 230A may be referred to as extra low-power devices, devices in the second region 230B may be referred to as low-power devices, and devices in the third region 230C may be referred to as high-power devices or high-performance devices. The devices in the second region 230B and the third region 230C may have improved speed because of reduced channel widths and increased source/drain volumes.

Although FIGS. 2-15 and 17-21 illustrate GAA transistors, other examples of semiconductor devices (e.g., FinFETs (fin field-effect transistors), complementary field effect transistors (CFET), other multigate devices, three-dimensional integrated circuits (3DIC), chip-on-wafer-on-substrate (CoWoS) packages) may benefit from aspects of the present disclosure.

Although not intended to be limiting, one or more embodiments of the present disclosure provide many benefits to a semiconductor structure. For example, the present disclosure provides semiconductor structures with reduced parasitic capacitance, improved current, and increased speed. For example, By reducing thicknesses of gate spacer layers before recessing the source/drain regions, widths of the source/drain features may be enlarged, channel widths may be reduced, and the overall performance of the semiconductor structure may be improved.

In one exemplary aspect, the present disclosure is directed to a method. The method includes providing a stack of alternating channel layers and sacrificial layers, forming a dummy gate stack over a channel region of the stack, depositing a first spacer layer along sidewalls of the dummy gate stack, depositing a second spacer layer along sidewalls of the first spacer layer, trimming the second spacer layer, performing a first etching process in a source/drain region of the stack, thereby forming a shallow recess, performing a second etching process to expand the shallow recess, thereby forming a source/drain recess, forming a source/drain feature in the source/drain recess, forming a contact etch stop layer (CESL) over the source/drain feature, forming an interlayer dielectric (ILD) layer over the CESL, and replacing the dummy gate stack and the sacrificial layers with a metal gate stack. The source/drain feature comprises a first layer adjacent a sidewall of the channel layers and a second layer away from the sidewall of the channel layers.

In some embodiments, trimming the second spacer layer comprises performing an anisotropic etching to the second spacer layer. In some embodiments, the method further includes trimming the first spacer layer to reduce a thickness of the first spacer layer. In some embodiments, before performing the second etching process, the method further includes forming a nitride layer on an exposed surface in the shallow recess, forming the nitride layer comprises flowing a nitrogen-containing gas over the shallow recess. In some embodiments, trimming the second spacer layer exposes the sidewalls of the first spacer layer. In some embodiments, a sidewall of the source/drain recess is laterally recessed from a sidewall of the first spacer layer thereabove. In some embodiments, the first spacer layer and the second spacer layer have a same composition.

In another exemplary aspect, the present disclosure is directed to a method. The method includes providing a structure. The structure includes a first region comprising a first fin-shaped structure and first dummy gates over the first fin-shaped structure, and a second region comprising a second fin-shaped structure and second dummy gates over the second fin-shaped structure, the first fin-shaped structure extends lengthwise along a first direction, and the first dummy gates extend lengthwise along a second direction different from the first direction. The method further includes forming first spacer layers over the first dummy gates and the second dummy gates, forming second spacer layers over the first spacer layers, trimming the second spacer layers in the second region but not in the first region, etching a first source/drain region of the first fin-shaped structure and a second source/drain region of the second fin-shaped structure, forming a first source/drain feature in the first source/drain region and a second source/drain feature in the second source/drain region, replacing the first dummy gates with first metal gates, and replacing the second dummy gates with second metal gates. The second source/drain feature is wider than the first source/drain feature, the first source/drain feature includes a first layer adjacent a sidewall of a first channel region of the first fin-shaped structure and a second layer away from the sidewall of the first channel region.

In some embodiments, trimming the second spacer layers in the second region but not in the first region includes forming a patterned mask layer to cover the first region while exposing the second region, etching the second spacer layers in the second region using the patterned mask layer as an etch mask, and removing the patterned mask layer. In some embodiments, etching the first source/drain region of the first fin-shaped structure and the second source/drain region of the second fin-shaped structure forms a first source/drain recess in the first source/drain region and a second source/drain recess in the second source/drain region, a sidewall of the first source/drain recess is laterally recessed from a sidewall of the second spacer layers thereabove, and a sidewall of the second source/drain recess is laterally recessed from a sidewall of the first spacer layers thereabove. In some embodiments, the first source/drain feature has a first depth, and the second source/drain feature has a second depth greater than the first depth. In some embodiments, the first source/drain feature has a V-shaped profile, and the second source/drain feature has a U-shaped profile. In some embodiments, the method further includes trimming the first spacer layers in the second region but not in the first region, thereby reducing thicknesses of the first spacer layers in the second region. In some embodiments, the first channel region has a first channel width along the first direction, and a second channel region of the second fin-shaped structure has a second channel width along the first direction and less than the first channel width. In some embodiments, etching the first source/drain region of the first fin-shaped structure and the second source/drain region of the second fin-shaped structure includes performing a first etching process to form a first initial recess in the first source/drain region and a second initial recess in the second source/drain region, flowing a nitrogen-containing gas in the first initial recess and the second initial recess, and performing a second etching process to extend the first initial recess and the second initial recess, thereby forming a first source/drain recess and a second source/drain recess, respectively. In some embodiments, flowing the nitrogen-containing gas forms a first nitridation layer in the first initial recess and a second nitridation layer in the second initial recess, the second nitridation layer is thicker than the first nitridation layer.

In yet another exemplary aspect, the present disclosure is directed to a semiconductor structure. The semiconductor structure includes a first region and a second region. The first region includes a first active region, first gate structures over the first active region, first gate spacers disposed on sidewalls of the first gate structures, and a first source/drain feature disposed between adjacent first gate structures. The second region includes a second active region, second gate structures over the second active region, second gate spacers disposed on sidewalls of the second gate structures, and a second source/drain feature disposed between adjacent second gate structures. The first active region and the second active region extend lengthwise along a first direction, and the first gate structures extend lengthwise along a second direction different from the first direction. The first gate spacers have a first thickness and the second gate spacers have a second thickness less than the first thickness, the first thickness and the second thickness along the first direction. The first gate structures have a first pitch, the second gate structures have a second pitch greater than the first pitch, the first pitch and the second pitch along the first direction. The first gate structures comprise a gate dielectric layer over the first active region and a gate electrode over the gate dielectric layer. A dielectric constant of the gate dielectric layer is greater than a dielectric constant of the first gate spacers.

In some embodiments, the first active region has a first channel width under one of the first gate structures, and the second active region has a second channel width under one of the second gate structures, the first channel width and the second channel width are along the first direction, and the first channel width is greater than the second channel width. In some embodiments, the semiconductor structure further includes a third region including a third active region, third gate structures over the third active region, third gate spacers disposed on sidewalls of the third gate structures, and a third source/drain feature disposed between adjacent third gate structures, the third gate spacers have a third thickness less than the second thickness and along the first direction. In some embodiments, the third gate structures have a third pitch greater than the second pitch and along the first direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a stack of alternating channel layers and sacrificial layers;
forming a dummy gate stack over a channel region of the stack;
depositing a first spacer layer along sidewalls of the dummy gate stack;
depositing a second spacer layer along sidewalls of the first spacer layer;
trimming the second spacer layer;
performing a first etching process in a source/drain region of the stack, thereby forming a shallow recess;
performing a second etching process to expand the shallow recess, thereby forming a source/drain recess;
forming a source/drain feature in the source/drain recess, wherein the source/drain feature comprises a first layer adjacent a sidewall of the channel layers and a second layer away from the sidewall of the channel layers;
forming a contact etch stop layer (CESL) over the source/drain feature;
forming an interlayer dielectric (ILD) layer over the CESL; and
replacing the dummy gate stack and the sacrificial layers with a metal gate stack.

2. The method of claim 1, wherein trimming the second spacer layer comprises performing an anisotropic etching to the second spacer layer.

3. The method of claim 1, further comprising trimming the first spacer layer to reduce a thickness of the first spacer layer.

4. The method of claim 1, before performing the second etching process, further comprising forming a nitride layer on an exposed surface in the shallow recess,
wherein forming the nitride layer comprises flowing a nitrogen-containing gas over the shallow recess.

5. The method of claim 1, wherein trimming the second spacer layer exposes the sidewalls of the first spacer layer.

6. The method of claim 1, wherein a sidewall of the source/drain recess is laterally recessed from a sidewall of the first spacer layer thereabove.

7. The method of claim 1, wherein the first spacer layer and the second spacer layer have a same composition.

8. A method, comprising:
providing a structure comprising:
a first region comprising a first fin-shaped structure and first dummy gates over the first fin-shaped structure, and
a second region comprising a second fin-shaped structure and second dummy gates over the second fin-shaped structure,
wherein the first fin-shaped structure extends lengthwise along a first direction, and the first dummy gates extend lengthwise along a second direction different from the first direction;
forming first spacer layers over the first dummy gates and the second dummy gates;
forming second spacer layers over the first spacer layers;
trimming the second spacer layers in the second region but not in the first region;
etching a first source/drain region of the first fin-shaped structure and a second source/drain region of the second fin-shaped structure;
forming a first source/drain feature in the first source/drain region and a second source/drain feature in the second source/drain region, wherein the second source/drain feature is wider than the first source/drain feature, wherein the first source/drain feature comprises a first layer adjacent a sidewall of a first channel region of the first fin-shaped structure and a second layer away from the sidewall of the first channel region;
replacing the first dummy gates with first metal gates; and
replacing the second dummy gates with second metal gates.

9. The method of claim 8, wherein trimming the second spacer layers in the second region but not in the first region comprises:
forming a patterned mask layer to cover the first region while exposing the second region;
etching the second spacer layers in the second region using the patterned mask layer as an etch mask; and
removing the patterned mask layer.

10. The method of claim 8, wherein etching the first source/drain region of the first fin-shaped structure and the second source/drain region of the second fin-shaped structure forms a first source/drain recess in the first source/drain region and a second source/drain recess in the second source/drain region,
wherein a sidewall of the first source/drain recess is laterally recessed from a sidewall of the second spacer layers thereabove, and a sidewall of the second source/drain recess is laterally recessed from a sidewall of the first spacer layers thereabove.

11. The method of claim 8, wherein the first source/drain feature has a first depth, and the second source/drain feature has a second depth greater than the first depth.

12. The method of claim 8, wherein the first source/drain feature has a V-shaped profile, and the second source/drain feature has a U-shaped profile.

13. The method of claim 8, further comprising trimming the first spacer layers in the second region but not in the first region, thereby reducing thicknesses of the first spacer layers in the second region.

14. The method of claim 8, wherein the first channel region has a first channel width along the first direction, and a second channel region of the second fin-shaped structure has a second channel width along the first direction and less than the first channel width.

15. The method of claim 8, wherein etching the first source/drain region of the first fin-shaped structure and the second source/drain region of the second fin-shaped structure comprises:
performing a first etching process to form a first initial recess in the first source/drain region and a second initial recess in the second source/drain region;
flowing a nitrogen-containing gas in the first initial recess and the second initial recess; and
performing a second etching process to extend the first initial recess and the second initial recess, thereby forming a first source/drain recess and a second source/drain recess, respectively.

16. The method of claim 15, wherein flowing the nitrogen-containing gas forms a first nitridation layer in the first initial recess and a second nitridation layer in the second initial recess,
wherein the second nitridation layer is thicker than the first nitridation layer.

17. A semiconductor structure, comprising:
a first region comprising a first active region, first gate structures over the first active region, first gate spacers disposed on sidewalls of the first gate structures, and a first source/drain feature disposed between adjacent first gate structures; and
a second region comprising a second active region, second gate structures over the second active region, second gate spacers disposed on sidewalls of the second gate structures, and a second source/drain feature disposed between adjacent second gate structures,
wherein the first active region and the second active region extend lengthwise along a first direction, and the first gate structures extend lengthwise along a second direction different from the first direction,
wherein the first gate spacers have a first thickness and the second gate spacers have a second thickness less than the first thickness, the first thickness and the second thickness along the first direction,
wherein the first gate structures have a first pitch, the second gate structures have a second pitch greater than the first pitch, the first pitch and the second pitch along the first direction,
wherein the first gate structures comprise a gate dielectric layer over the first active region and a gate electrode over the gate dielectric layer,
wherein a dielectric constant of the gate dielectric layer is greater than a dielectric constant of the first gate spacers.

18. The semiconductor structure of claim 17, wherein the first active region has a first channel width under one of the first gate structures, and the second active region has a second channel width under one of the second gate structures,
wherein the first channel width and the second channel width are along the first direction, and
wherein the first channel width is greater than the second channel width.

19. The semiconductor structure of claim 17, further comprising a third region comprising a third active region, third gate structures over the third active region, third gate spacers disposed on sidewalls of the third gate structures, and a third source/drain feature disposed between adjacent third gate structures,
wherein the third gate spacers have a third thickness less than the second thickness and along the first direction.

20. The semiconductor structure of claim 19, wherein the third gate structures have a third pitch greater than the second pitch and along the first direction.
